(19) United States
(12) Patent Application Publication
(10) Pub. No.: US 2020/0341063 A1
(43) Pub. Date: Oct. 29, 2020

(54) SYSTEMS AND METHODS FOR ANALYZING OPERATION OF MOTORS

(71) Applicant: SCHNEIDER ELECTRIC USA, INC., Boston, MA (US)

(72) Inventor: Jon Andrew Bickel, Murfreesboro, TN (US)

(73) Assignee: SCHNEIDER ELECTRIC USA, INC., Boston, MA (US)

(21) Appl. No.: 16/909,193

(22) Filed: Jun. 23, 2020

Related U.S. Application Data
(63) Continuation-in-part of application No. 14/405,702, filed on Dec. 4, 2014, now Pat. No. 10,718,813.

(51) Int. Cl. G01R 31/34; G01R 21/133; G01R 27/16

(52) U.S. Cl. CPC G01R 31/343; G01R 27/16; G01R 21/133

(57) ABSTRACT

A method for analyzing operation of a motor includes capturing time-domain energy-related signals associated with at least one motor using at least one intelligent electronic device electrically coupled to the at least one motor. The signals are processed to determine an operating state of the at least one motor, and the signals are converted to frequency representations of the signals in response to it being determined the operating state of the at least one motor indicates the at least one motor is at least one of energizing/starting and in a normal operating state/running. At least one of power data and impedance data is determined at one or more frequencies in the frequency-domain from the frequency representations of the time-domain energy-related signals, and an issue associated with the at least one motor is identified based on analysis of at least one of the determined power data and/or the determined impedance data.

### CROSS REFERENCE TO RELATED APPLICATIONS

This application is a Continuation-in-Part (CIP) application of and claims the benefit of and priority to U.S. application Ser. No. 14/405,702, filed on Dec. 4, 2014, which application is a 35 U.S.C. § 371 application claiming the benefit of and priority to Patent Cooperation Treaty (PCT) Application No. PCT/US2012/041711, filed on Jun. 8, 2012, which applications are incorporated by reference herein in their entirety.

### FIELD

The present disclosure relates generally to systems and methods for automatically identifying anomalies or problems with electrical apparatuses, such as induction motors.

### BACKGROUND

For certain applications, motors are an essential piece of electrical equipment, in large, industrial facilities and residential buildings alike. They are used in a wide range of applications—from the large three-phase induction motors that the drive reactor coolant pumps in nuclear generation stations, to the small universal motors that drive a vacuum cleaner. Motors are a crucial component of every nation's economy not only because of the work they perform, but also because of the considerable amount of energy they consume.

The most commonly used type of motor is a polyphase induction motor with over 90% of those being squirrel-cage induction motors. Polyphase induction motors are popular for several reasons including: they are relatively inexpensive; they enjoy a rudimentary design; they are readily replaced; they have reliable operation; and they have a range of mounting styles and environmental enclosures.

Due to the significant capital and operational investments made by enterprises in motors—investments that impact the bottom line—knowing the state of their condition is vital. Induction motors are generally robust, but they can fail prematurely. Causes of motor failures include poor maintenance practices, improper lubrication, harsh operating environment, inadequate source voltage, or misapplication of the motor. All of these issues have one commonality: excessive temperature rise. Excessive heat is the nemesis of motors; temperature rise can originate in the bearings (lubrication, alignment, etc.), in the windings (design, voltage, etc.), or can be imposed by external conditions (ambient temperature, atmosphere, etc.).

One way of monitoring the health of a motor is to monitor the current used by the motor. These monitoring techniques do not account for variations in the voltage that can affect the inrush current and the full-load current (FLA). The inrush (or locked-rotor) current is the current drawn by the motor when it is initially started up from a stopped position. The actual inrush current value is typically much higher than the rated full-load current and is usually stated by the manufacturer on the motor's nameplate as the locked-rotor current. Many operators correctly assume that as a motor's terminal voltage decreases below its rated voltage, the motor's inrush current and full-load current will increase. However more counter-intuitively, if the motor's terminal voltage increases above its rated voltage, the motor's inrush and full-load currents will also increase. Misunderstanding the relationships between voltages and currents can result in misdiagnosed motor conditions or assumptions that an induction motor is operating within normal range.

Known motor monitoring schemes do not account for the relationships of high and low voltage motor terminal variations with the motor's startup and run currents. They either assume that whatever variation in the voltage that exists contributes a negligible effect on the motor's performance or assume that the actual voltage across the motor's power terminals is constant relative to the rated voltage. In real world induction motors, its terminal voltage varies and can have a significant impact on motor performance that can indicate a potential mechanical problem with the motor. More importantly, not accounting for variations at the motor's terminals can provide misleading conclusions regarding the motor's health.

### SUMMARY

The invention disclosed in this document provides new systems and methods for evaluating data captured by Intelligent Electronic Devices (IEDs) to analyze, identify, and report potential motor issues. Aspects described herein apply to asset management, which refers to helping the customer understand the condition of the equipment within their facility. Providing the customer with an early indication of a problem allows them to more efficiently and cost effectively address the problem.

Aspects of the present disclosure can help customers recognize problems with their motors, which are a major capital investment and a key operational component for many industrial and commercial customers. The systems, algorithms, and methods described herein provide motor diagnostics that are heretofore unavailable.

According to an aspect of the present disclosure, a method for analyzing operation of a motor, for example, to automatically determine an anomalous condition of the motor, is provided. The method includes the steps of: receiving, by an intelligent electronic device, a measured inrush or starting current flowing into an induction motor during a startup period of the induction motor; receiving, by the intelligent electronic device, a voltage measured across power terminals of the induction motor during the startup period; determining, using a controller, a voltage variation by comparing the voltage measured across the power terminals with a rated voltage of the induction motor; calculating, using the controller or another controller, a characteristic function that includes the voltage measured across the power terminals and the inrush or starting current; comparing, using the controller or another controller, the characteristic function with a baseline using the voltage variation to determine whether a criterion is satisfied; and responsive to the criterion being satisfied, providing, using the controller or another controller, an indication of an anomalous operation of the induction motor.

The baseline can be a theoretical function that includes a rated inrush or locked-rotor current and the rated voltage. The comparing can include determining whether the characteristic function deviates from the theoretical function at the same voltage variation. The theoretical function can be a theoretical impedance of the induction motor operating under rated conditions. The theoretical impedance can be calculated using a rated inrush or locked-rotor current and the rated voltage. The characteristic function can be an impedance of the induction motor calculated using the measured current and the voltage measured across the power terminals.

The theoretical function can be a theoretical power flow to the induction motor operating under rated conditions. The theoretical power flow can be calculated using a rated inrush current or locked-rotor current and the rated voltage. The characteristic function can be a power flow to the induction motor using the measured current and the voltage measured across the power terminals. The power flow to the induction motor can be real power, reactive power, or apparent power.

The baseline can be a theoretical function that includes a rated inrush or locked-rotor current and the rated voltage. The comparing can include a statistical comparison of the characteristic function and historical characteristic functions including historical values of voltage measured across the power terminals and inrush or starting current supplied to the induction motor.

The measured inrush or starting current and the voltage measured across the power terminals can be received responsive to the measured inrush or starting current being applied to the induction motor for energizing the induction motor transitioning the induction motor from a stopped to a starting operating condition. The characteristic function can be an impedance of the induction motor. The baseline can be a theoretical impedance of the induction motor operating under rated conditions. The theoretical impedance can be calculated using a rated inrush or locked-rotor current and the rated voltage.

The comparing can include determining whether the impedance at the voltage variation deviates from the theoretical impedance at the same voltage variation by more than a threshold, and if so, determining that the criterion is satisfied, wherein the threshold is a fixed threshold, a relative threshold, or a statistical threshold.

The comparing can include a statistical comparison of the impedance at the voltage variation and a historical impedance value that includes a historical value of a voltage measured across the power terminals and an inrush or starting current supplied to the induction motor prior to the receiving the current. The characteristic function can be a power flow to the induction motor. The baseline can be a theoretical power flow to the induction motor operating under rated conditions. The theoretical power flow can be calculated using a rated inrush or locked-rotor current and the rated voltage. The power flow can be calculated using the measured current and the voltage measured across the power terminals.

The comparing can include determining whether the power flow at the voltage variation deviates from the theoretical power flow at the same voltage variation by more than a threshold, and if so, determining that the criterion is satisfied. The threshold can be a fixed threshold, a relative threshold, or a statistical threshold.

The comparing can include a statistical comparison of the power flow at the voltage variation and a historical power flow value at the same voltage variation, the historical power flow value including a historical value of a voltage measured across the power terminals and an inrush or starting current supplied to the induction motor prior to the receiving the current.

The indication of the anomaly can include an alarm indicating the amount by which the voltage measured across the power terminals or the measured current deviates from the rated voltage or a rated locked-rotor current of the induction motor. The indication of the anomaly can include whether an impedance of the induction motor at the voltage variation during the startup period is above or below an expected impedance of the induction motor at the voltage variation. The impedance can be calculated using the measured current and the voltage measured across the power terminals. The expected impedance at the voltage variation can be calculated or derived based on a rated inrush or locked-rotor current of the induction motor and the rated voltage including the voltage variation.

In response to the impedance exceeding the expected impedance, the anomaly can indicate potential damage to a rotor or a rotor bar of the induction motor, a potential poor connection relative to one or both power terminals of the induction motor or to a stator winding of the induction motor. In response to the impedance being below the expected impedance, the anomaly can indicate a potential short-circuit in a winding of a coil around a pole of the induction motor or between adjacent coils of the induction motor or a potential insulation breakdown in the induction motor.

The method can further include: receiving, by the intelligent electronic device, a measured steady-state current flowing into the induction motor during a steady-state operation of the induction motor; receiving, by the intelligent electronic device, a second steady-state voltage measured across the power terminals during the steady-state operation; determining, using the controller or another controller, a steady-state voltage variation by comparing the measured steady-state voltage with the rated voltage; calculating, using the controller or another controller, a second characteristic function that includes the measured steady-state voltage and the measured steady-state current; comparing, using the controller or another controller, the second characteristic function with a second baseline using the steady-state voltage variation to determine whether a steady-state criterion is satisfied; and responsive to the steady-state criterion being satisfied, providing, using the controller or another controller, the indication of the anomaly.

According to another aspect of the present disclosure, a non-transitory computer-readable medium encoded with instructions to cause one or more controllers to implement a method is provided. The method includes: receiving a measured inrush or starting current flowing into an induction motor during a startup period of the induction motor; receiving a voltage measured across power terminals of the induction motor during the startup period; determining a voltage variation by comparing the voltage measured across the power terminals with a rated voltage of the induction motor; calculating a characteristic function that includes the voltage measured across the power terminals and the inrush or starting current; comparing the characteristic function with a baseline using the voltage variation to determine whether a criterion is satisfied; and responsive to the criterion being satisfied, providing an indication of an anomaly of the induction motor.

According to yet another aspect of the present disclosure, a method of automatically determining an anomalous condition of an induction motor is provided. The method includes: receiving, by an intelligent electronic device, an inrush or starting current flowing into and a voltage measured across power terminals of an induction motor at an initial startup period of the induction motor; comparing, by the intelligent electronic device, the received voltage with a rated voltage of the induction motor to produce a voltage variation; calculating, using a controller, a characteristic function that includes the received voltage and the inrush or starting current; comparing, using the controller or another controller, the characteristic function with a baseline using the voltage variation to determine whether a first criterion is satisfied; receiving, by the intelligent electronic device, a steady-state current flowing into and a second voltage measured across the power terminals during a steady-state operation of the induction motor; comparing, using the controller or another controller, the second received voltage with the rated voltage to produce a second voltage variation; calculating, using the controller or another controller, a second characteristic function that includes the second received voltage and the steady-state current; comparing, using the controller or another controller, the second characteristic function with a second baseline using the second voltage variation to determine whether a second criterion is satisfied; and responsive to the first criterion or the second criterion being satisfied, providing, using the controller or another controller, an indication of an anomalous condition of the induction motor.

The above-discussed systems and methods of automatically determining an anomalous condition of a motor focuses on the time-domain analysis of energy-related signals/data (e.g., voltage, current, power, impedance, etc.) to automatically identify anomalous condition(s) of induction motors, for example, by normalizing the power flow to/from and/or impedance of a motor relative to the voltage measured across the motor's terminals. In one example implementation, the time-domain starting and/or operational/run current and corresponding voltage of the motor is measured, and a coincident time-domain voltage variation between the measured voltage and the motor's rated voltage is determined. The time-domain power flow and/or impedance at the corresponding voltage variation is calculated to determine an expected power flow and/or impedance at the corresponding measured voltage variation. Additionally, the actual power flow and/or impedance in the time-domain is compared against a nominal or expected power flow and/or impedance or a statistical comparison is carried out on a historical set of power flow and/or impedance values within an expected range at the corresponding voltage variation. When the measured time-domain values deviate from the expected values, an alarm may be triggered to indicate a potential anomaly with the motor or external thereto.

Additional systems and methods for analyzing operation of a motor are also provided herein. In particular, the additional systems and methods call for analyzing time-series (time-domain) data during the start and/or operation/running of an induction motor. Measurement data is captured during a motor's start/run/operation and compared to historical measurement data from the same motor. The induction motor's power flow and/or impedance (i.e., both are defined as relationships of voltage and current) are analyzed to determine changes over time, which may indicate potential motor issues.

An extension of the ideas described in this application is to evaluate calculated power and/or impedance from the motor's measured voltage and corresponding current in the frequency-domain using Fourier analysis techniques. For example, the power flows associated with starting an induction motor may be analyzed using a short-term Fourier transformer (STFT) method while the power associated with the steady-state operation/running of an induction motor may be analyzed using more standard Fourier transform methods (such as discrete Fourier transforms (DFTs) or fast Fourier transforms (FFTs)), or other approaches (such as Goertzel filters at one or more discrete frequencies).

As will be appreciated further from discussions below, particularly in the Detailed Description section of this disclosure, analyzing an induction motor's normalized start/run/operation energy-related signals/data (referred to hereinafter as “energy-related signals” for simplicity) in the time-domain provides an efficient method to identify motor issues. However, this approach can be developed further by evaluating the energy-related signals (e.g., voltage and current data) in the frequency-domain. As in the time-domain, voltage data can be used to normalize the effects of voltage variations in the frequency-domain. Power and impedance data, for example, are inherently derived from voltage and current data (e.g., S=V×I*; Z=V÷I); and therefore, can be used to normalize these two important parameters (i.e., voltage and current). The frequency resolution is dependent on the length of the voltage and current waveform capture(s). For example, a 60 cycle long waveform capture can provide 1-Hertz resolution in a 60 Hertz-based system, and a 30 cycle long waveform capture can provide 2-Hertz resolution in a 60-Hertz based system.

According to an aspect of the present disclosure, a method for analyzing operation of a motor (by evaluating energy-related signals in the frequency-domain) includes capturing time-domain energy-related signals associated with at least one motor using at least one IED electrically coupled to the at least one motor. The time-domain energy-related signals are processed to determine an operating state of the at least one motor, and in response to determining the operating state of the at least one motor indicates the at least one motor is at least one of being in an energizing/starting condition and being in a normal operating state/steady-state/running condition, the time-domain energy-related signals measured/captured by the IED are converted to frequency representations of the time-domain energy-related signals (e.g., using Fourier analysis). At least one of power data and impedance data is determined/calculated at one or more frequencies in the frequency-domain from the frequency representations of the time-domain energy-related signals, and at least one of the determined power data and/or the determined impedance data is analyzed (e.g., compared, trended, etc.) at the one or more frequencies to identify an issue (or issues) associated with the at least one motor in at least one of the energizing/starting condition and in the normal operating state/steady-state/running condition. In accordance with embodiments of this disclosure, characteristics of the determined power data and/or the determined impedance data are indicative of the issue(s) associated with the at least one motor in at least one of energizing/starting condition and in a normal operating state/steady-state/running condition.

In accordance with some embodiments of this disclosure, characteristics of the determined power data and/or the determined impedance data at the one or more frequencies may be analyzed and/or trended over time to identify the issue(s) associated with the at least one motor at least one of being in an energizing/starting condition and/or being in a normal operating state/steady-state/running condition. The evaluated characteristics may include, for example, amplitude(s) exceeding predetermined threshold(s), directional and/or magnitude changes of power flows based on the phase angle relationship of the voltage and currents at a specific frequency, etc.

In accordance with some embodiments of this disclosure, the one or more frequencies at which the at least one of the power data and impedance data is determined and/or evaluated include at least one of a harmonic frequency component(s), an interharmonic frequency component(s), and a sub-harmonic frequency component(s). In one example implementation of the invention, the one or more frequencies include a fundamental frequency/nominal system frequency, and analyzing at least the determined power data and/or the determined impedance data at the one or more frequencies to identify an issue associated with the at least one motor in at least one of being in an energizing/starting condition and being in a normal operating state/steady-state/running condition, includes: comparing the determined power data and/or the determined impedance data at the fundamental frequency/nominal system frequency to previously determined power data and/or previously determined impedance data at the fundamental frequency/nominal system frequency; identifying a relative similarity of the determined power data and/or the determined impedance data at the fundamental frequency/nominal system frequency and the previously determined power data and/or the previously determined impedance data at the fundamental frequency/nominal system frequency; and analyzing the relative similarity of the determined power data and/or the determined impedance data and the previously determined power data and/or the previously determined impedance data on at least one non-fundamental frequency component to identify the issue associated with the at least one motor in at least one of being in an energizing/starting condition and being in a normal operating state/steady-state/running condition.

In some embodiments, other relevant information (i.e., besides the determined power data and/or the determined impedance data) may also be analyzed to identify the issue(s) associated with the at least one motor in at least one of being in an energizing/starting condition and/or being in a normal operating state/steady-state/running condition. For example, duty-cycle information may be analyzed to identify the issue(s) associated with the at least one motor in at least one of being in an energizing/starting condition and/or being in a normal operating state/steady-state/running condition. In one example implementation of the invention, the determined power data and/or the determined impedance data in the time-domain and/or the frequency-domain may be compared against duty-cycle characteristics of the at least one motor to identify the issue(s) associated with the at least one of being in an energizing/starting condition and/or being in a normal operating state/steady-state/running condition. The duty-cycle characteristics of the at least one motor may include, for example, at least one of: starting characteristics of the at least one motor, running characteristics of the at least one motor, and inoperative characteristics of the at least one motor. The at least one of the starting characteristics of the at least one motor, the running characteristics of the at least one motor, and the inoperative characteristics of the at least one motor, may include, for example, at least one of: a starting duration of the at least one motor, run duration of the at least one motor, period(s) between starts of the at least one motor, period(s) between the at least one motor being de-energized/turned-off and the at least one motor being energized/turned-on, and load of the at least one motor when energized/started.

In some embodiments, the above-discussed method for analyzing operation of a motor further includes taking one or more actions in response to identifying at least one issue associated with the at least one of being in an energizing/starting condition and/or being in a normal operating state/steady-state/running condition. In one aspect of this disclosure, taking one or more actions in response to identifying at least one issue associated with the at least one motor in at least one of being in an energizing/starting condition and/or being in a normal operating state/steady-state/running condition, includes: identifying at least one means for addressing the at least one issue associated with the at least one motor in at least one of being in an energizing/starting condition and/or being in a normal operating state/steady-state/running condition; and applying at least one of the at least one identified means for addressing/mitigating the at least one issue associated with the at least one of being in an energizing/starting condition and/or being in a normal operating state/steady-state/running condition.

In accordance with some embodiments of this disclosure, the at least one of the at least one identified means for addressing the at least one issue associated with the at least one motor at least one of being in an energizing/starting condition and/or being in a normal operating state/steady-state/running condition is applied based on at least one of the priority and severity of the at least one issue. Additionally, in accordance with some embodiments of this disclosure, the at least one of the at least one identified means for addressing the at least one issue associated with the at least one motor at least one of being in an energizing/starting condition and/or being in a normal operating state/steady-state/running condition is automatically applied. Further, in accordance with some embodiments of this disclosure, the at least one of the at least one identified means for addressing the at least one issue associated with the at least one motor at least one of being in an energizing/starting condition and/or in a normal operating state/steady-state/running condition is applied, at least in part, in response to user input. Additionally, in accordance with some embodiments of this disclosure, the at least one of the at least one identified means for addressing the at least one issue associated with the at least motor at least one of being in an energizing/starting condition and/or being in a normal operating state/steady-state/running condition is selected based, at least in part, on user-specified criteria. The user-specified criteria may include, for example, potential issue severity, issue trend (i.e., progressive deterioration), motor cost, criticality of the motor to a process, operational or safety considerations, maintenance scheduling, and so forth.

In accordance with further embodiments of this disclosure, the at least one of the at least one identified means for addressing the at least one issue associated with the at least one motor at least one of being in an energizing/starting condition and/or being in a normal operating state/steady-state/running condition is selected based on an analysis of a number of learned factors or criteria (e.g., using machine learning techniques). For example, the at least one IED responsible for capturing the time-domain energy-related signals to identify the issue(s) associated with the at least one motor may continuously (or periodically) measure/capture/monitor information about a system (e.g., electrical/power system) including the at least one IED and the at least one motor, and learn information about the system (e.g., system characteristics, such as device types, number of devices, cost constraints, etc.) to generate the learned factors or criteria. The learning occurring to generate the learned factors or criteria may indicate, for example, what time-domain and frequency-domain characteristics indicate what motor issue(s) (or impending issue(s)) is/are present. Examples of the learned factors or criteria may include, for example, active power(s), apparent power(s), reactive power(s), energy(ies), harmonic distortion(s), power factor(s), magnitude/direction of harmonic power(s), harmonic voltage(s), harmonic current(s), interharmonic current(s), interharmonic voltage(s), magnitude/direction of interharmonic power(s), magnitude/direction of sub-harmonic power(s), individual phase currents, phase angle(s), impedance(s), sequence component(s), total voltage harmonic distortion, total current harmonic distortion, three-phase current(s), phase voltage(s), line voltage(s) and/or other similar/related parameters. In accordance with some embodiments of this disclosure, the learned factors or criteria may be weighted (with the weighting factor being adjusted over time based on learned information) to provide the most up-to-date (and possibly cost and energy effective) solution. It is understood that the learned factors or criteria may be obtained over one or more learning periods (in some instances, over many learning periods). It is also understood that the learning periods may include one or more supervised learning periods in some embodiments. Supervised learning means that some variable(s) may be used to teach the calculation engine which issues have more value than others. These variable(s) may include or be associated with the learned factors or criteria, for example.

In another aspect of this disclosure, taking one or more actions in response to identifying at least one issue associated with the at least one motor at least one of being in an energizing/starting condition and/or being in a normal operating state/steady-state/running condition, includes: generating and/or initiating at least one alarm indicating the at least one identified issue (or potential issue(s)). In accordance with some embodiments of this disclosure, the at least one alarm indicates at least one of: change in power, change in energy, change in phase balance/imbalance, change in voltage, change in power factor, change in one or more harmonic/interharmonic/sub-harmonic power flow directions, change in harmonic distortion, change in current, change in any other measured and/or derived parameter, and/or changes in digital and/or analog inputs and/or outputs. In accordance with some embodiments of this disclosure, the at least one alarm is communicated via at least one of: a report, a text, an email, audibly, and an interface of a screen/display (e.g., of a user device in communication with the at least one IED and/or the at least one motor). In some embodiments, the at least one alarm is prioritized. The prioritization may be based on any number of factors. For example, as will be described further below in connection with FIGS. 8-10, the prioritization may be based on magnitude of at least one of the sidebands, ratio of the sideband(s) to the fundamental frequency, and/or at least one specific frequency component(s) being considered/evaluated/measured, as a few examples.

It is understood that many other actions may be taken in addition to (or instead of) the above-discussed actions. A few further examples of actions that may be taken include: indicating a potential motor issue exists on at least one circuit, stopping the at least one motor, derating the at least one motor (i.e., reducing the load), automating placing an order for parts, scheduling maintenance to occur at some interval commensurate with the potential severity of the problem or the operational criticality of the at least one motor, providing recommendations for responding to the identified issue(s) (i.e., so that a system user may address the issue(s)), and so forth.

In accordance with some embodiments of this disclosure, the time-domain energy-related signals captured using the at least one IED responsible for capturing the time-domain energy-related signals to identify the issue(s) associated with the at least one motor, include at least one of: a voltage signal, a current signal, and/or a derived energy-related value. In some embodiments, the derived energy-related value includes at least one of: a calculated, computed, estimated, derived, developed, interpolated, extrapolated, evaluated, and otherwise determined additional energy-related value from the at least one of the voltage signal and/or the current signal. In some embodiments, the derived energy-related value includes at least one of: active power, apparent power, reactive power, energy, harmonic distortion, power factor, magnitude/direction of harmonic power(s), harmonic voltage(s), harmonic current(s), interharmonic current(s), interharmonic voltage(s), magnitude/direction of interharmonic power(s), magnitude/direction of sub-harmonic power(s), individual phase currents, phase angle(s), impedance(s), sequence component(s), total voltage harmonic distortion, total current harmonic distortion, three-phase current(s), phase voltage(s), line voltage(s) and/or other similar/related parameters. In some embodiments, the derived energy-related value includes at least one energy-related characteristic, the energy-related characteristic including magnitude, direction, phase angle, percentage, ratio, level, duration, associated frequency components, impedance, energy-related parameter shape, and/or decay rate.

In some embodiments, the at least one IED capturing the time-domain energy-related signals includes at least one metering device. The at least one metering device may correspond, for example, to at least one metering device in an electrical/power system. The electrical system may be associated with at least one load, process, building, facility, watercraft, aircraft, or other type of structure, for example.

As used herein, an IED is a computational electronic device optimized to perform a particular function or set of functions. Examples of IEDs include smart utility meters, power quality meters, microprocessor relays, digital fault recorders, and other metering devices. IEDs may also be imbedded in variable speed drives (VSDs), uninterruptible power supplies (UPSs), circuit breakers, relays, transformers, or any other electrical apparatus. IEDs may be used to perform measurement/monitoring and control functions in a wide variety of installations. The installations may include utility systems, industrial facilities, warehouses, office buildings or other commercial complexes, campus facilities, computing co-location centers, data centers, power distribution networks, or any other structure, process or load that uses electrical energy. For example, where the IED is an electrical power monitoring device, it may be coupled to (or be installed in) an electrical power transmission or distribution system and configured to sense/measure and store data (e.g., waveform data, logged data, I/O data, etc.) as electrical parameters representing operating characteristics (e.g., voltage, current, waveform distortion, power, etc.) of the electrical distribution system. These parameters and characteristics may be analyzed by a user to evaluate potential performance, reliability and/or power quality-related issues, for example. The IED may include at least a controller (which in certain IEDs can be configured to run one or more applications simultaneously, serially, or both), firmware, a memory, a communications interface, and connectors that connect the IED to external systems, devices, and/or components at any voltage level, configuration, and/or type (e.g., AC, DC). At least certain aspects of the monitoring and control functionality of an IED may be embodied in a computer program that is accessible by the IED.

In some embodiments, the term “IED” as used herein may refer to a hierarchy of IEDs operating in parallel and/or tandem. For example, an IED may correspond to a hierarchy of energy meters, power meters, and/or other types of resource meters. The hierarchy may comprise a tree-based hierarchy, such a binary tree, a tree having one or more child nodes descending from each parent node or nodes, or combinations thereof, wherein each node represents a specific IED. In some instances, the hierarchy of IEDs may share data or hardware resources and may execute shared software. It is understood that hierarchies may be non-spatial such as billing hierarchies where IEDs grouped together may be physically unrelated.

In some embodiments, the metering devices (e.g., IEDs) and equipment/loads of the above and below described systems and methods are installed, located and/or derived from different respective locations (i.e., a plurality of locations) or metering points in the electrical system. A particular IED (e.g., a second IED) may be up-line (or upstream) from another IED (e.g., a third IED) in the electrical system while being down-line (or downstream) from a further IED (e.g., a first IED) in the electrical system, for example.

As used herein, the terms “up-line” and “down-line” (also sometimes referred to as “upstream” and “downstream”, respectively) are used to refer to electrical locations within an electrical system. More particularly, the electrical locations “up-line” and “down-line” are relative to an electrical location of an IED collecting data and providing this information. For example, in an electrical system including a plurality of IEDs, one or more IEDs may be positioned (or installed) at an electrical location that is up-line relative to one or more other IEDs in the electrical system, and the one or more IEDs may be positioned (or installed) at an electrical location that is down-line relative to one or more further IEDs in the electrical system. A first IED or load that is positioned on an electrical circuit up-line from a second IED or load may, for example, be positioned electrically closer to an input or source of the electrical system (e.g., an electrical generator or a utility feed) than the second IED or load. Conversely, a first IED or load that is positioned on an electrical circuit down-line from a second IED or load may be positioned electrically closer to an end or terminus of the electrical system than the other IED.

A first IED or load that is electrically connected in parallel (e.g., on an electrical circuit) with a second IED or load may be considered to be “electrically” up-line from said second IED or load in embodiments, and vice versa. In embodiments, algorithm(s) used for determining a direction of a power quality event (i.e., up-line or down-line) is/are located (or stored) in the IED, cloud, on-site software, gateway, etc. As one example, the IED can record an electrical event's voltage and current phase information (e.g., by sampling the respective signals) and communicatively transmit this information to a cloud-based system. The cloud-based system may then analyze the voltage and current phase information (e.g., instantaneous, root-mean-square (rms), waveforms and/or other electrical characteristic) to determine if the source/origin of an energy-related transient was electrically up-line or down-line from where the IED is electrically coupled to the electrical system (or network).

It is understood that each IED of the at least one IED disclosed herein may be electrically coupled to one or more motors of the at least one motor, and be configured to capture the time-domain energy-related signals associated with each motor of the one or more motors the IED is responsible for monitoring. In accordance with some embodiments of this disclosure, two or more IEDs of the at least one IED may monitor and capture the time-domain energy-related signals associated with at least one same motor (e.g., for redundancy). For example, one IED may be configured to monitor a single motor while another IED in the electrical system may be upstream monitoring the same motor plus additional parallel loads (including other motors).

According to another aspect of the present disclosure, a method for analyzing the operation of a motor includes capturing time-domain energy-related signals associated with at least one motor using at least one IED electrically coupled to the at least one motor, and processing the time-domain energy-related signals to determine an operating state (e.g., energizing/starting, energized/running, de-energizing/stopping, de-energized/stopped) of the at least one motor. In response to determining the operating state of the at least one motor indicates the at least one motor is at least one of energizing/starting and in a normal operating state/running, the time-domain energy-related signals are converted to frequency representations of the time-domain energy-related signals. The frequency representations of the time-domain energy-related signals are analyzed to identify whether an issue exists associated with the at least one motor at least one of being in an energizing/starting condition and/or being in a normal operating state/steady-state/running condition. In accordance with some embodiments of this disclosure, characteristics of the frequency representations are indicative of the issue associated with the at least one motor at least one of being in an energizing/starting condition and in a normal operating state/steady-state/running condition.

A system for analyzing operation of a motor is also disclosed herein. According to an aspect of the present disclosure, the system includes at least one processor and at least one memory device coupled to the at least one processor. The at least one processor and the at least one memory device are configured to capture time-domain energy-related signals associated with at least one motor and process the time-domain energy-related signals to determine an operating state of the at least one motor. In response to determining the operating state of the at least one motor indicates the at least one motor at least one of being in an energizing/starting condition and being in a normal operating state/steady-state/running condition, the at least one processor and the at least one memory device are configured to convert the time-domain energy-related signals to frequency representations of the time-domain energy-related signals. The at least one processor and the at least one memory device are also configured to calculate at least one of power data and impedance data at one or more frequencies in the frequency-domain from the frequency representations of the time-domain energy-related signals, and analyze at least the determined power data and/or the determined impedance data at the one or more frequencies to identify an issue associated with the at least one motor at least one of being in an energizing/starting condition and/or being in a normal operating state/steady-state/running condition. In accordance with some embodiments of this disclosure, the determined power data and the determined impedance data are indicative of the issue associated with the at least one motor at least one of being in an energizing/starting condition and/or being in a normal operating state/steady-state/running condition.

In accordance with some embodiments of this disclosure, the time-domain energy-related signals are captured by at least one IED in the system. The at least one IED may be electrically coupled to the at least one motor. In accordance with some embodiments of this disclosure, the at least one motor corresponds to a plurality of motors, and the time-domain energy-related signals for each motor of the plurality of motors are captured by at least one IED in the system. The at least one IED may be electrically coupled to the plurality of motors.

In accordance with some embodiments of this disclosure, characteristics of the determined power data and/or the determined impedance data at the one or more frequencies are analyzed and/or trended over time to identify the issue associated with the at least one motor at least one of being in an energizing/starting condition and/or being in a normal operating state/steady-state/running condition.

It is understood that other aspects of the systems and methods discussed above and below related to systems and methods for analyzing operation of a motor may be implemented by the above-discussed system (and other discussed systems and methods). Thus, unless otherwise stated, features from one of the systems and methods discussed above and below may be combined with features of other ones of the systems and methods discussed described below, for example, to capture the various advantages and aspects of systems and methods associated with analyzing operation of a motor. For example, in accordance with some embodiments of this disclosure, one or more actions may be taken by one or more elements of or associated with the system discussed directly above to address the at least one issue associated with the at least one motor at least one of being in an energizing/starting condition and/or being in a normal operating state/steady-state/running condition. The one or more elements may include, for example, a control system associated with the system. The control system may be a meter, an IED (e.g., an IED of the at least one IED), on-site/head-end/Edge software (i.e., a software system), a cloud-based control system, a gateway, a system in which data is routed over the Ethernet or some other communications system, etc. In embodiments in which the control system is not the at least one IED or does not include the at least one IED, for example, the control system may be communicatively coupled to the at least one IED. The control system may also be communicatively coupled to at least one of: a cloud-based system, on-site software, a gateway, and another head-end or Edge system associated with the electrical system.

In some embodiments, the control system may automatically control at least one component in the electrical system to address the at least one issue associated with the at least one of being in an energizing/starting condition and/or being in a normal operating state/steady-state/running condition. The at least one component may correspond to a component of or associated with the at least one motor, for example. In some embodiments, the at least one component is controlled in response to a control signal generated by the control system, with the control signal indicating/providing for adjustment of at least one parameter associated with the at least one component, other associated components/loads/equipment, or the electrical system.

As will be appreciated from this disclosure, analyzing energy-related data in the frequency-domain (e.g., harmonics/interharmonics/sub-harmonics) provides further insights into potential motor issues that may be arising. For example, motor rotors often experience cracked or broken rotor bars, dynamic eccentricity and/or bearing damage that change the motor's rotating flux and/or field components. Changes in the motor's rotating flux components are reflected in the motor current signals, which are measurable using IEDs. Evaluating the motor's power data and/or impedance data (via the processes described above) accounts for variations in the motor's source voltage, leading to a more consistent analysis from start to start.

The foregoing and additional aspects of the present disclosure will be apparent to those of ordinary skill in the art in view of the detailed description of various aspects, which are made with reference to the drawings, a brief description of which is provided next.

### BRIEF DESCRIPTION OF THE DRAWINGS

The foregoing and other advantages of the present disclosure will become apparent upon reading the following detailed description and upon reference to the drawings.

FIG. 1 is a functional block diagram of devices and modules that can be used to carry out an implementation of aspects of the present disclosure;

FIG. 2 shows three plots depicting how variations in the voltage of a motor from its rated voltage are expected to affect the performance of the motor as a function of the locked-rotor current (LRA), the full-load current (FLA), and the power factor (PF) of the motor;

FIG. 3 are plots of real, reactive, and apparent power flows as measured during the motor startup period as a function of time;

FIG. 4 are plots of the apparent power flow that is expected to the motor during the startup period for three different voltage variations;

FIG. 5 are plots of the motor's three-phase impedances as measured during the startup period;

FIG. 6 is a flowchart illustrating an example method for analyzing operation of a motor in the time-domain in accordance with embodiments this disclosure;

FIG. 7 is a flowchart illustrating an example method for analyzing operation of a motor in the time-domain and/or in the frequency-domain in accordance with embodiments of this disclosure;

FIG. 8 is a flowchart illustrating another example method for analyzing operation of a motor in the time-domain and/or in the frequency-domain in accordance with embodiments of this disclosure;

FIG. 9 illustrates example power data from an induction motor load in the frequency-domain; and

FIG. 10 illustrates further example power data from an induction motor load in the frequency-domain.

### DETAILED DESCRIPTION

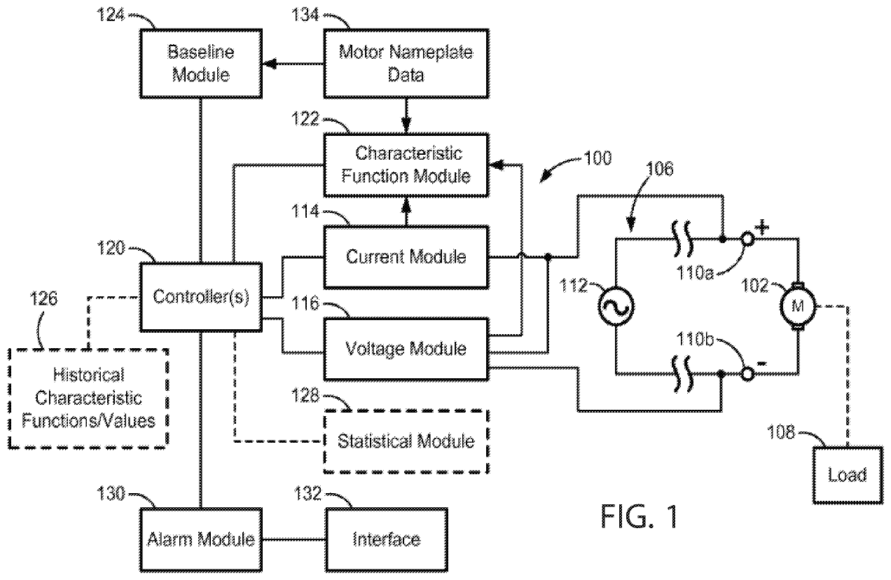

Referring to FIG. 1, an intelligent electronic device (IED) 100, such as a permanently-installed power monitoring device, can provide a great deal of information about an induction motor 102. By monitoring the voltage, current, and temperature, the IED 100 can provide data on many aspects of an induction motor including the quality of the motor's terminal voltage, energy usage by the motor, motor loading concerns, excessive motor cycling, environmental concerns, and a motor's starting characteristics. When an induction motor 102 is initially energized by an electrical circuit 106 (during the startup period), a large amount of current flows into the motor's stator windings because the motor's stationary rotor appears to be the equivalent of a short circuit. This initial or startup flow of current (sometimes referred to as an inrush current or a locked-rotor current) may be up to 10 times the motor's rated full-load current (FLA). This startup flow of current will be referred to herein as a starting current, in contradistinction from a run current, which is the current used by the motor 102 under steady-state or normal operating load conditions. The initial magnitude of the inrush current is dependent on the electrical characteristics of the motor 102; not the mechanical characteristics of the motor 102 or its attached load 108. As the motor's stator is magnetized, the electrical energy is converted into kinetic energy and the rotor begins to rotate. The interaction between the magnetic flux and the current conductors in the rotor produces a torque that corresponds to the rotation of the magnetic field. The other components and modules of FIG. 1 will be identified next and discussed in more detail below.

The IED 100 includes a current module 114 and a voltage module 116. The current module 114 includes a sensor for measuring a current flowing into the induction motor 102. The voltage module 116 includes a sensor for measuring a voltage across the power terminals 110a,b of the induction motor 102 (although only one set of power terminals are shown, for three-phase motors, as is already known, three sets of power terminals are present). The IED 100 includes a controller, such as one of the one or more controllers 120 shown in FIG. 1. In implementations involving multiple controllers 120, the controllers 120 can be distributed across a network. The particular architecture is not salient to implementing the aspects of the present disclosure. For example, the IED 100 can include one of the controllers 120, and one or more other controllers 120 can be distributed over a network among one or more other computing devices, such as servers, computers, or other processing units. The one or more controllers 120 are coupled to a characteristic function module 122 and a baseline module 124.

It should be noted that the algorithms, block diagrams, or methods illustrated and discussed herein as having various modules or blocks or components that perform particular functions and interact with one another. It should be understood that these modules are merely segregated based on their function for the sake of description and can represent computer hardware and/or executable software code that is stored on one or more non-transitory computer-readable medium/media for execution by one or more controllers 120 on appropriate computing hardware. The various functions of the different modules, blocks, or components can be combined or segregated as hardware and/or software stored on one or more non-transitory computer-readable medium or media in any manner, and can be used separately or in combination with one another.

The characteristic function module 122 and the baseline module 124 receive motor nameplate data 134 that includes nameplate rating information relating to the induction motor 102. Nameplate rating information includes a rated full load current (FLA), a rated locked-rotor current (LRA), a rated or nominal voltage (such as 460V), a rated power factor (PF), among other conventional nameplate rating information. An optional database of historical characteristic functions or values 126 can be coupled to the one or more controllers 120. The one or more controllers 120 can be coupled to an optional statistical module 128 and to an alarm module 130. The alarm module 130 is coupled to an interface 132 for communicating information from the alarm module 130 to an external system that can include a display device, for example, for displaying information from the alarm module 130.

The impedance of the induction motor 102 during startup can be calculated using the following equations:

$$\begin{matrix}{Z}_{m} = ( \frac{{I}_{FLC}}{{I}_{LRC}} ) ( \frac{{V}_{m}^{2} cos {∅}_{m}}{{P}_{m}} ) & ( Eqn . 1 ) \\ {R}_{m} = \frac{( {P}_{m} ) ( {I}_{LRC} ) cos {∅}_{s}}{3 ( {I}_{LFC} ) ( {I}_{LRC}^{2} ) cos {∅}_{m}} & ( Eqn . 2 ) \\ {X}_{m} = \sqrt{{Z}_{m}^{2} - {R}_{M}^{2}} & ( Eqn . 3 )\end{matrix}$$

Where,

Zₘ is the total startup impedance of the motor in Ohms,

Rₘ is the startup resistance of the motor in Ohms,

Xₘ is the startup reactance of the motor in Ohms,

I_{LRC} is the locked-rotor current in Amperes,

I_{FLC} is the rated full-load current of the motor at full load in Amperes,

Vₘ is the rated voltage of the motor in volts,

Pₘ is the rated power of the motor in Watts,

Cos φₘ is the motor's power factor at full load, and

Cos φₛ is the motor's power factor at startup (e.g., under locked-rotor conditions).

A motor is stressed mechanically, electrically, and thermally during startup. Over time, these stresses can result in changes in the motor's electrical characteristics, and subsequently its impedance. Equation 1 shown above for Zₘ provides the theoretical total startup impedance for an induction motor; however, it does not provide any indication of changes in the motor's electrical characteristics. The purpose of this feature is to ascertain a motor's condition during startup using empirical data from a measurement device. These changes can be reviewed to identify potential degradation of the motor.

Aspects of the present disclosure determine the relationship between a motor's expected performance against its actual performance to identify potential motor issues. Furthermore, aspects of the present disclosure evaluate a motor's start and run parameters over successive operational cycles to provide an indication of motor anomalies. While Equations 1-3 listed above provide theoretical impedance values for an induction motor under ideal (rated) conditions, any variance of the actual applied voltage at the motor's terminals 110a,b will impact the starting and running values.

When a low voltage (i.e., below its rated voltage) is applied to a motor's terminals 110a,b, the current drawn by the motor 102 increases accordingly to provide the same electrical power to the load connected to the motor 102. If the applied current exceeds the motor's full-load current (FLA) rating, the motor's temperature can increase beyond the motor's recommended rating and may damage or reduce the motor's operating life.

Similarly, applying a high voltage (i.e., above its rated voltage) across the motor's terminals 110a,b can also increase the motor's current due to the effects of saturation. The saturation curve for a motor is related to the amount of iron in the stator (i.e., the motor's design). Once the motor's terminal voltage reaches a certain magnitude, the motor's current will increase because the inductive reactance of the motor decreases. Not only does the motor's efficiency decrease, but its temperature increases and may damage or reduce the motor's operating life. High voltage conditions can also adversely impact other types of equipment including transformers and lighting components (ballasts, bulbs, etc.).

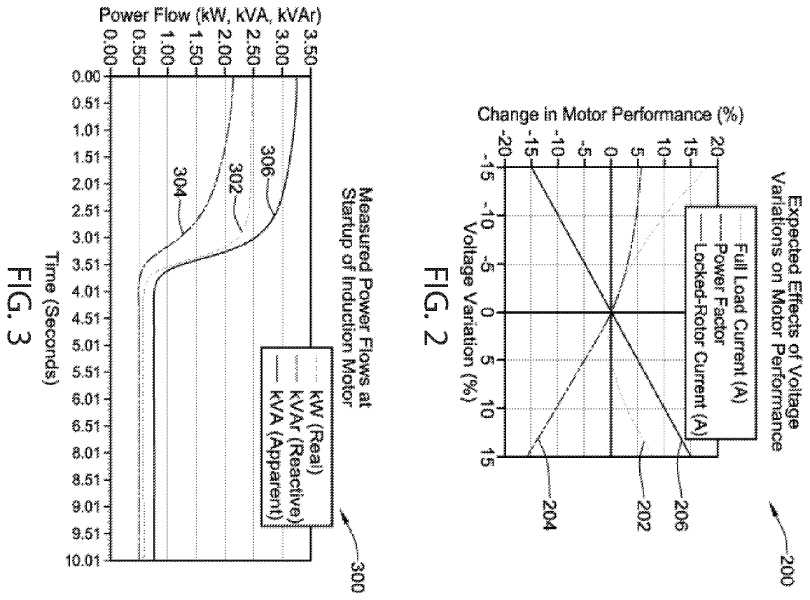

FIG. 2 is a plot 200 illustrating the effects of terminal voltage variations on the starting (measured inrush) current (LRA) 206, full-load current (FLA) (or run current) 202, and power factor (PF) 204 of the induction motor 102, plotted against a percentage change in motor performance. This becomes even more important in practical applications because a motor's rated voltage can (and often does) vary from the electrical system's nominal voltage. For example, a standard voltage rating for a NEMA (National Electrical Manufacturers Association) induction motor is 460 volts; however, these motors are generally connected to 480-volt nominally rated electrical systems 112. Assuming 480 volts (such as from a polyphase ac source 112) are applied to a 460-volt motor's terminals 110a,b, there can be a voltage variation of approximately +4.35%. Based on the relationships described in FIG. 2, a voltage increase from 0% to 5% at the motor's terminals 110a,b will result in a 5% increase of the motor's 102 starting or inrush current (see curve 206), almost no change to its full-load current (FLA) (see curve 202), and a 5% reduction in its power factor (PF) (see curve 204). Several other operational parameters of the motor 102 are affected as well including its starting and maximum torque, efficiency, and even its run temperature. The rated voltage and rated locked-rotor current (LRA) can be specified in motor nameplate data 134 stored in a memory device.

Equations 4-5 listed below provide a general relationship between the induction motor's 102 terminal voltage 110a,b and its full-load current (FLA), power factor (PF), and starting locked-rotor current (LRA).

FLA=(−0.00004696969)x⁴+(0.0001944444)x³+(0.0674810606)x²+(0.38427777)x+0.1948051948 (Eqn. 4)

PF=(0.0000439393939)x⁴+(0.00027777)x³−(0.0329545455)x²−(0.7905753968)x−0.1163419913 (Eqn. 5)

Percent change in Starting Amperage=x (Eqn. 6)

Where,

FLA is the full-load current as a percent of the motor's nominal (rated) value,

PF is the power factor as a percent of the motor's nominal (rated) value, and

x is the voltage variation of the motor's actual terminal voltage as a percent of the motor's nominal (rated) voltage value.

Equations 4-6 are used to plot the data for the curves in FIG. 2, and are bounded by a ±15% voltage variation at the motor's power terminals.

Typical evaluations, trends and comparisons of motor-starting characteristics (under inrush current conditions) are based on measured starting (e.g., measured inrush) currents, and do not consider the effects of a motor's terminal voltage on those current values. Normalizing a motor's inrush current with respect to the relationship of the measured terminal voltage (as measured across the terminals 110a,b) and nameplate rated voltage (such as stored as the motor nameplate data 134) can identify potential issues within motor 102. Aspects of the present disclosure provide at least two ways of evaluating motor issues: 1) using motor power flows (real, reactive, or apparent) at motor startup (e.g., under starting current or inrush conditions), and 2) motor input impedance (e.g., at the terminals 110a,b) at startup. Each of these implementations accounts for the voltage magnitude's influence (and how the voltage varies relative to the rated voltage) on motors during their most stressful operating period, namely at startup or under locked-rotor conditions.

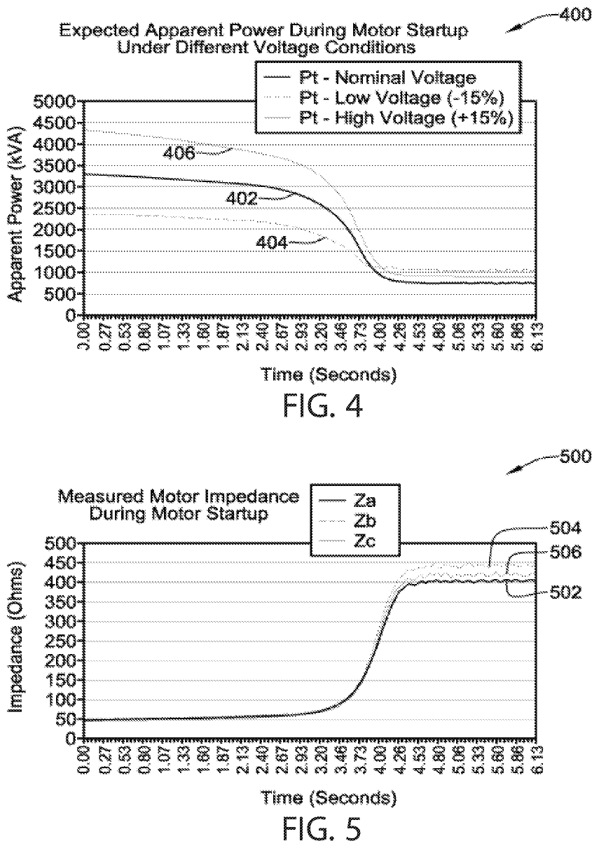

Evaluating power flows during the startup period of the induction motor 102 requires both voltage and current measurements. FIG. 3 is a plot 300 illustrating the changes in three types of power flows, namely, the real power (kW) 302, reactive power (kVAr) 304, and the apparent power (kVA) 306, during and following the startup period (expressed as time in seconds) of a small induction motor as measured by the IED 100. Using Equations 4 and 6 above, the expected initial power transient (when the motor is first started) and the steady-state power flow (when the motor is operating under full load conditions) can be approximated during a motor startup period. For example, FIG. 4 is a plot 400 of the expected apparent power values of the motor 102 starting under three different voltage conditions versus time in seconds: low voltage (−15% of the nominal or rated voltage) 404, nominal (rated) voltage 402, and high voltage (+15% of the nominal or rated voltage) 406. It is readily apparent that ignoring the influence of a motor's terminal voltage during the startup period directly affects the magnitude of the power (and current flows). Consequently, it is difficult to recognize whether the current changes between sequential motor starts are the result of motor problems or may be attributed to voltage variations.

It should be noted that the initial inrush current at the motor 102 is deterministic (Equation 6) based on voltage magnitudes and the impedances at the motor 102, assuming the motor 102 is operating within rated parameters. The full load current (FLA) is also deterministic (Equation 4), assuming the motor 102 is loaded at its nameplate rated load and operating within rated parameters. Low-voltage starting conditions will reduce a motor's starting torque, pull-up torque, and pullout torque, which could result in the motor's stalling.

Evaluating measured motor's power flows against theoretical or expected power flows can indicate potential internal problems or anomalies with a motor because the power flows are deterministic. Trending the power flow profiles can also indicate other problems with a motor including near-stall conditions, long starting times, and even the need to incorporate reduced voltage starting techniques.

A second aspect of the present disclosure evaluates the impedance downstream (relative to the electrical circuit 106) for the IED 100. Just as the motor's initial power flow during the startup period is deterministic based on voltage levels across the motor's terminals 110a,b, current levels provided to the motor 102, and the motor's impedance characteristics, so too is the motor's impedance. As shown in Equations 1, 2, and 3 above, a motor's rated resistance, reactance, and impedance at startup can be calculated. Each of the components in these equations is either estimable from measured data or provided on the motor's nameplate (and extracted from, for example, the motor nameplate data 134). The motor's resistance at startup is fixed; however, the reactance (and thus, impedance) is a function of frequency (including harmonic distortion). All are subject to Ohm's Law, so a motor's initial impedance values can be determined based on voltage and current values at startup (under locked-rotor conditions). Changes in an induction motor's predicted impedance based on actual measured values can indicate fundamental changes in the motor's design characteristics, which in turn indicate a potential problem or anomaly with the motor.

Similar to motor start power flow analysis described above, changes in impedance can be trended and analyzed accordingly. Once the expected startup impedance is determined through theoretical, derived and/or empirical data, statistical analysis of the data (or some other method) can be performed. For example, deviations of the impedance values exceeding some number of standard deviations, exceeding a fixed threshold, or exceeding a percentage of the average measurement (or minimum measurement) can initiate an alarm. FIG. 5 is a plot 500 of measured changes in a motor's impedance versus time (in seconds) using samples of measured voltage and current captured by the IED 102 during the motor's startup period through its steady-state (full-load conditions). The Za, Zb, and Zc components of the impedance of the motor 102 are represented by the curves 502, 504, 506, respectively, versus time.

The majority of induction motor electrical problems occur at startup due to the inherent stresses during that period. Of these problems, the majority exhibit low impedance characteristics. A decrease in the impedance can indicate shorted turns or windings, insulation damage or failure. For example, Y-connected motor windings exhibiting a shorted turn(s) will experience low-inductance measurements on two of the three phases. Likewise, A-connected windings exhibiting a shorted turn(s) will experience low inductance on only one of the three phases.

Some motors will exhibit high impedance characteristics due to various types of high-resistance connections, broken or cracked rotor bars, or some other source that resists the flow of current. Some causes of high-resistance connections include: corroded terminals, loose bus bars, corroded or damaged contacts, corroded fuse clips, open leads, loose cables, etc. An increase in impedance may indicate high-resistance connections, broken or cracked rotor bars, or another source that resists the flow of current. Any of these foregoing problems can be detected and indicated by the alarm module 130 and communicated via the interface 132 to an external system for display or further processing.

Aspects of the present disclosure can be deployed on a phase by phase basis or on an average of all three phases. Three-phase systems are not perfectly balanced, so each motor phase can experience different power flows and impedances at startup and run conditions. Each discrete phase can be tracked and trended accordingly.

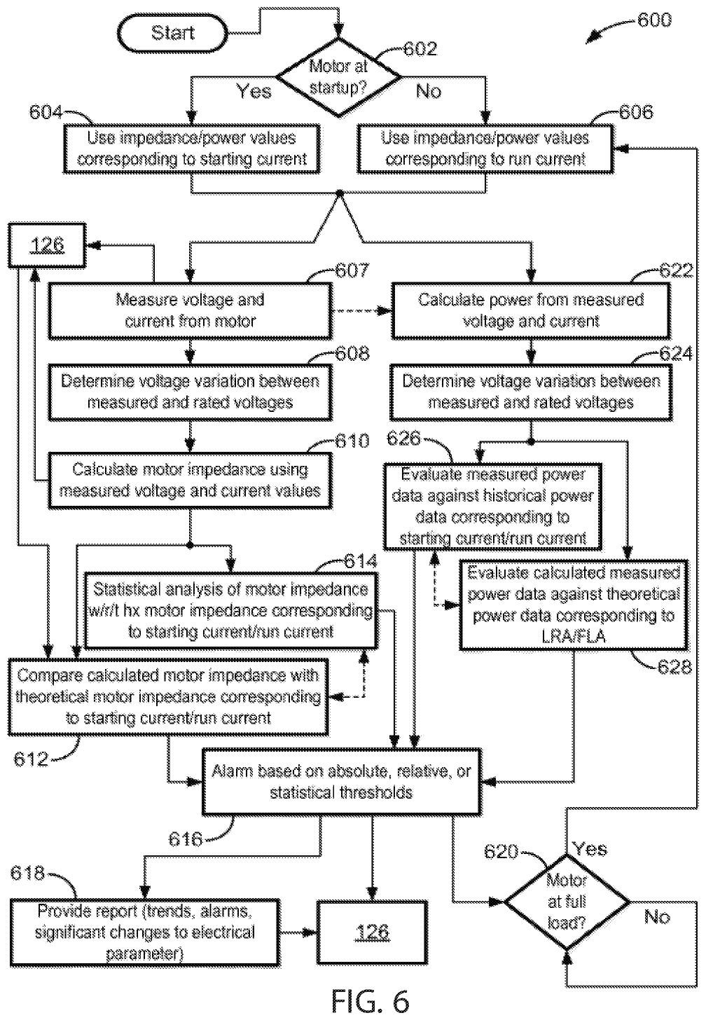

Referring to FIGS. 6-8, several flowcharts (or flow diagrams) are shown to illustrate various methods of the disclosure. Rectangular elements (typified by element 604 in FIG. 6), as may be referred to herein as “processing blocks,” may represent computer software and/or IED algorithm instructions or groups of instructions. Diamond shaped elements (typified by element 602 in FIG. 6), as may be referred to herein as “decision blocks,” represent computer software and/or IED algorithm instructions, or groups of instructions, which affect the execution of the computer software and/or IED algorithm instructions represented by the processing blocks. The processing blocks and decision blocks (and other blocks shown) can represent steps performed by functionally equivalent circuits such as a digital signal processor circuit or an application specific integrated circuit (ASIC).

The flow diagrams do not depict the syntax of any particular programming language. Rather, the flow diagrams illustrate the functional information one of ordinary skill in the art requires to fabricate circuits or to generate computer software to perform the processing required of the particular apparatus. It should be noted that many routine program elements, such as initialization of loops and variables and the use of temporary variables are not shown. It will be appreciated by those of ordinary skill in the art that unless otherwise indicated herein, the particular sequence of blocks described is illustrative only and can be varied. Thus, unless otherwise stated, the blocks described below are unordered; meaning that, when possible, the blocks can be performed in any convenient or desirable order including that sequential blocks can be performed simultaneously and vice versa. It will also be understood that various features from the flow diagrams described below may be combined in some embodiments. Thus, unless otherwise stated, features from one of the flow diagrams described below may be combined with features of other ones of the flow diagrams described below, for example, to capture the various advantages and aspects of systems and methods sought to be protected by this disclosure. It is also understood that various features from the flow diagrams described below may be separated in some embodiments. For example, while the flow diagrams illustrated in FIGS. 6-8 are shown having many blocks, in some embodiments the illustrated methods shown by these flowcharts may include fewer blocks or steps.

FIG. 6 is a flow diagram or algorithm 600 showing exemplary steps to automatically, under control of the one or more controllers 120, evaluate the condition of an induction motor 102. A method of automatically determining an anomalous condition of an induction motor, such as the induction motor 102, is disclosed herein. An example of an anomalous condition is a condition that causes the induction motor 102 to operate outside of its rated parameters or a condition that if continues unabated will cause the motor 102 to operate outside of its rated parameters or lead to damage or failure. Specific examples of anomalous conditions include a damaged rotor bar, a turn-to-turn short circuit. The machine-readable instructions corresponding to the steps of the algorithm 600 can be carried out by the one or more controllers 120 of or associated with IED 100 in conjunction with any combination of one or more of the modules 114, 116, 122, 124, 128, 130 shown in FIG. 1.

The algorithm 600 determines whether an operational condition of the motor 102 is in a startup period (602). The startup period includes a starting condition of the motor 102 immediately after a rated voltage is applied to its terminals 110a,b. During this startup period, the measured current corresponds to a measured inrush or starting current. Although the term locked-rotor current (LRA) is a fixed value given for a specific manufacturer's motor model, the term inrush current refers to a measured value of starting current during startup of a motor, and the term locked-rotor current refers to a theoretical or rated value of current during the startup of the motor, as specified on the nameplate by the manufacturer of the motor. The startup period is followed by a steady-state period during which the motor 102 draws a run or steady-state current. For convenience, these periods can be referred to herein as the starting period (when an inrush or starting current is drawn by the motor 102 at startup) or the running period (when the steady-state current is drawn by the motor 102 as it is driving the load 108 or during normal operation when the motor 102 reaches its steady-state speed). Measured values and calculated values can be stored in the database 126 for the starting period and separately for the running period. To emphasize, there are two periods of measurement and analysis. The first period is at startup when the motor 102 is energized and begins to rotate, during which it draws an inrush or starting current. This current can be up to 10 times higher than the normal current it draws during normal/steady-state operation, and is estimated by the locked-rotor current (LRA) on the motor's nameplate. The second period is when the motor is operating under steady-state conditions and is using nominal current. The algorithm 600 can be used to detect an anomaly in the motor 102 during either or both of these periods. It is not necessary to analyze the current and voltage during both starting and running periods, either will suffice. However, it is contemplated as well that the voltage and current of the motor can be analyzed during both periods.

If the motor is in a startup period (602), the algorithm 600 uses the impedance or power values corresponding to the measured starting current (604). Otherwise, the algorithm 600 uses the impedance of power values corresponding to the measured run current (606). For example, when a measured value is compared against a baseline by the baseline module 124, as explained below, the baseline includes values or calculations determined during the starting or running periods of motor operation or using theoretical or rated values under LRA or FLA conditions. Power and impedance are examples of a characteristic of electricity. A function can correspond to a mathematical equation that is implemented by the algorithm 600. An example of a characteristic function includes a mathematical equation that uses a characteristic (such as impedance or power) to determine an unknown quantity. These mathematical equations are solved by the characteristic function module 122, using inputs from the current module 114, the voltage module 116, and the motor nameplate data 134.

After determining whether to use starting current/LRA or run current/FLA functions or values, the algorithm 600 uses the current module 114 and the voltage module 116 to measure the voltage across the terminals 110a,b of the motor 102 and the current drawn by the motor during the starting or run current period, whichever is applicable (606). In the case of starting current, the current module 114 of the intelligent electronic device (IED) 100 receives a measured inrush current flowing into the induction motor 102 during a startup period of the induction motor 102 (606). Simultaneously with receiving the measured current, the voltage module of the IED 100 receives a voltage measured across its power terminals 110a,b during the same startup period (606). The measured voltage and current can be stored in the database 126.

The algorithm 600 determines a voltage variation between the measured voltage and a rated voltage, which can be retrieved from the motor nameplate data 134 (608). The difference between the measured and rated voltages produces a voltage variation, and the power flows to the motor or the impedance of the motor can be normalized to the voltage and compared against a baseline to account for the voltage variation at the motor's terminals 110a,b.

The characteristic function module 122 calculates a characteristic function that includes the measured voltage and the measured starting or run current, whichever is applicable (610). In this example, the characteristic function is an impedance function calculated by dividing the measured voltage by the measured current using Ohm's Law. The calculated impedance can be stored in the database 126 along with a corresponding timestamp indicating a time that the current and voltage were measured.

The algorithm 600 can do either or both of a statistical analysis or a theoretical comparison using the measured impedance. The algorithm 600 can compare, using a statistical analysis carried out by the statistical module 128, the calculated impedance with historical impedances using the voltage variation to determine whether a criterion is satisfied (612). The historical impedances at different voltage variations can produce a baseline (used by the baseline module 124) for an excepted range of impedances at various voltage variations. When the measured impedance at the voltage variation varies from a statistical comparison of historical impedances at the same voltage variation, the algorithm 600 can determine that the criterion is satisfied. The criterion can include whether a statistically significant outcome exists as a result of the statistical comparison carried out by the statistical module 128 or whether the statistical comparison produces a probability or likelihood that the measured impedance varies significantly from the baseline impedance. Instead of or in addition to doing a statistical comparison of the measured impedance versus historical impedance values at the same voltage variation, the algorithm 600 can do a “brute force” comparison of the calculated impedance at the voltage variation with a theoretical or rated impedance at the same voltage variation under rated LRA or FLA conditions, whichever was selected in response to block 602 above (614). Here, the baseline is represented by a theoretical impedance using the rated LRA or FLA current and the rated voltage of the motor 102 at the voltage variation. The baseline impedance represents an expected impedance at a voltage corresponding to the rated voltage and the voltage variation. For example, if the rated voltage is 460V, but the measured voltage is 465V, the voltage variation is +5V, and the theoretical or expected impedance of the motor 102 is calculated at 465V. If the measured impedance using the measured current and voltage deviates from the expected impedance, the algorithm 600 determines that a criterion is satisfied, indicating that an anomaly may exist relative to the induction motor 102. The criterion can be satisfied when the measured impedance deviates from the theoretical impedance at the voltage variation by more than a fixed threshold, a relative threshold (such as expressed as a percentage), or based on a statistical threshold such as a standard deviation.

If the criterion is satisfied, the alarm module 130 can provide an alarm (616) and a report indicating a trend, an alarm, or a significant change to an electrical parameter (618). For example, the report can indicate how the motor's impedance is trending over time on a plot, for example, to provide a visual indication of the motor's impedance during starting and/or run current periods. Deviations from the motor's impedance from nominal or baseline will be normalized to the voltage so that any voltage variation will be accounted for in the trend report. The report can indicate an alarm and the nature of the alarm. For example, if the impedance is higher than expected, the report can indicate potential damage to the motor's rotor or rotor bars or a potential poor connection relative to the motor's terminals 110a,b or a potential intermittent or poor connection with one or more of the stator windings of the motor. If the impedance is lower than expected, the report can indicate a potential short-circuit in a winding or windings of a coil around a pole of the motor 102 or between adjacent coils of the motor or a potential insulation breakdown that might be caused by vibration or thermal/electrical stress in the windings. The report can indicate a significant change to an electrical parameter, such as the impedance of or power flow to the motor 102. If the impedance or power flow dips or spikes suddenly, well beyond nominal or baseline expectations, the report can indicate that immediate attention may be warranted. The output of blocks 616 and 618 can be stored in the database 126. The report can be communicated via the interface 132 to another system, such as a computer that includes a display device for displaying the report.

The algorithm 600 checks whether the motor is running at a nominal load current (620), and if so, returns to block 606. At block 606, the motor has completed its startup period and is operating at its nominal running current, which means that the motor is rotating a load 108 at or near the expected design speed of the motor 102. The length of time that the motor 102 takes to achieve nominal operation varies by the motor and can be programmed into the algorithm 600. For example, the power flow to the motor 102 can be monitored and when it reaches a relatively stable value (see FIG. 3, for example, starting at about 4 seconds after motor initial startup), the algorithm 600 can determine that the motor 102 is operating under nominal or steady-state conditions. Alternately, a fixed time, such as 5 or 10 seconds or some other wait period after the motor is turned on can be determined to be the normal running period. The characteristic function module 122 calculates a power flow (real power, reactive power, or apparent power) from the measured voltage and the inrush or nominal (steady-state) current drawn by the motor under starting or running conditions (622). The algorithm 600 determines the voltage variation between the measured voltage under inrush or nominal conditions and the rated voltage from the motor nameplate data 134 (624). The statistical module 128 evaluates or compares the measured (calculated from the measured voltage and current) power flow (real, reactive, or apparent) at the voltage variation (see FIGS. 3-4 for example) against historical power flow data for starting or running periods stored in the database 126 at or near the same voltage variation (626). Thus, if the motor is just starting and the current to the motor corresponds to a locked-rotor current, the characteristic function module 122 calculates the power flow at the voltage variation (e.g., 465V or +5V from the nominal or rated voltage of 460V) at startup of the motor 102, such as shown in FIG. 3. This calculated value is compared by the statistical module 128 against historical power flow data at the same voltage variation using statistical analysis to determine whether the calculated value deviates in a statistically significant way from the baseline or expected or theoretical power flow.

Alternately or additionally, the algorithm 600 can evaluate or compare the power flow value calculated from the measured starting or run (steady-state) current and the associated motor voltage with a theoretical or expected or baseline power flow value at the same voltage variation using the rated LRA or FLA current and the rated voltage from the motor nameplate data 134 and the voltage variation (see FIG. 3) (628). The algorithm 600 proceeds to block 616 and optionally to block 618 as described above.

The baseline can correspond to a theoretical function that includes a rated LRA or FLA current and the rated voltage. The database 126 can store these theoretical functions (e.g., corresponding to impedance or power flow) along with the corresponding voltage variation for the starting period and separately for the FLA period of motor operation.

As illustrated above, the method associated with algorithm 600 focuses on the time-domain analysis of energy-related signals (e.g., voltage, current, power, impedance, etc.) to automatically identify anomalous condition(s) of induction motors by normalizing the voltage measured across its terminals relative to the motor's power flow(s) and/or impedance. Analyzing an induction motor's start/run/operation normalized data in the time-domain provides an efficient method to identify motor degradation. However, in accordance with embodiments of this disclosure, this efficient method can be taken a step further by evaluating the energy-related signals (e.g., voltage and current data) in the frequency-domain.

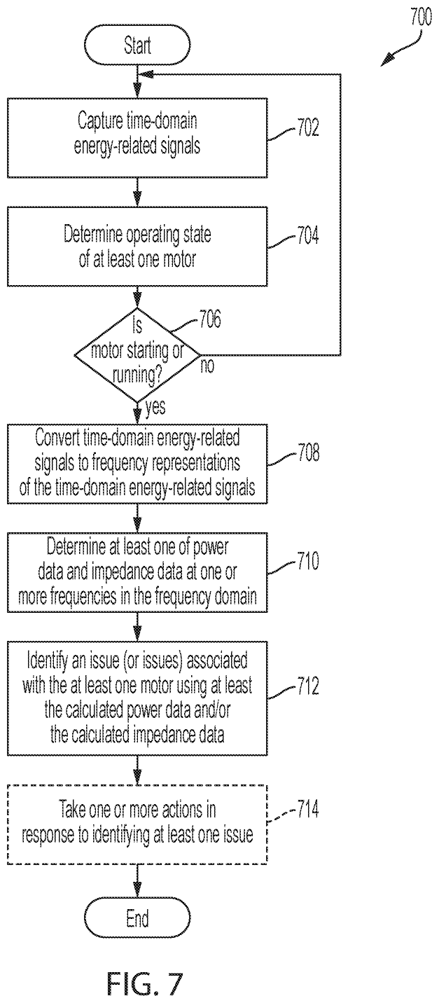

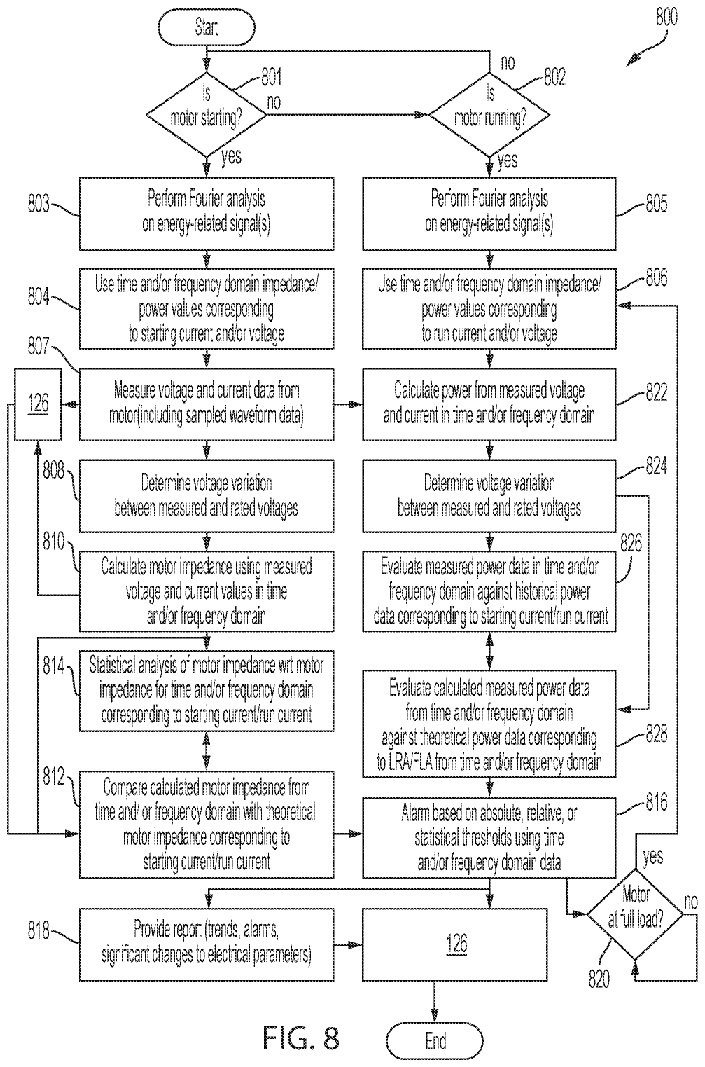

Referring to FIGS. 7 and 8, shown are flow diagrams or algorithms 700, 800 illustrating example methods for analyzing operation of a motor in accordance with embodiments of this disclosure by evaluating the energy-related signals in the frequency-domain. Similar to the method illustrated by the flow diagram or algorithm 600 shown in FIG. 6, the methods illustrated by the flow diagrams or algorithms 700, 800 may be implemented by the one or more controllers 120 of or associated with IED 100 in conjunction with any combination of one or more of the modules 114, 116, 122, 124, 128, 130 shown in FIG. 1. It is also contemplated that the methods may additionally or alternatively be implemented remote from the IED, for example, in at least one of: a cloud-based system, on-site/edge software, a gateway, or another head-end system. In accordance with some embodiments of this disclosure, the IED corresponds to more than one IED, and therefore is referred to as at least one IED in certain instances. It is understood that anywhere the term IED is used in this disclosure, the term may refer to one or more IEDs (or at least one IED).

It will be understood from FIGS. 7 and 8 that analyzing energy-related signals in the frequency-domain (e.g., harmonics/interharmonics/sub-harmonics) provides further insights into potential motor issues that may be arising. For example, motor rotors often experience cracked or broken rotor bars, dynamic eccentricity and/or bearing damage that change the motor's rotating flux components. Changes in the motor's rotating flux and/or field components are reflected in the motor current signals, which may be measurable using IEDs. Evaluating the motor's power data and impedance data (via the process described above) accounts for variations in the motor's source voltage, leading to a more consistent analysis from start to start.

As illustrated in FIG. 7, the method shown by the flow diagram or algorithm 700 begins at block 702, where time-domain energy-related signals (or waveforms) associated with at least one motor are measured and data is captured, collected, stored, etc. by at least one IED (and/or control system) electrically coupled to the at least one motor. The at least one IED may be installed or located, for example, at a respective metering point of a plurality of metering points in an electrical system, and the at least one motor may be installed or located proximate to the respective metering point.

The time-domain energy-related signals captured by the at least one IED may include, for example, at least one of: a voltage signal, a current signal, and a derived energy-related value. In some embodiments, the derived energy-related value includes at least one of: a calculated, computed, estimated, derived, developed, interpolated, extrapolated, evaluated, and otherwise determined additional energy-related value from the at least one of the voltage signal and/or the current signal. In some embodiments, the derived energy-related value includes at least one of: active power(s), apparent power(s), reactive power(s), energy(ies), harmonic distortion(s), power factor(s), magnitude/direction of harmonic power(s), harmonic voltage(s), harmonic current(s), interharmonic current(s), interharmonic voltage(s), magnitude/direction of interharmonic power(s), magnitude/direction of sub-harmonic power(s), individual phase current(s), phase angle(s), impedance(s), sequence component(s), total voltage harmonic distortion(s), total current harmonic distortion(s), three-phase current(s), phase voltage(s), line voltage(s) and/or other similar/related parameters. In some embodiments, the derived energy-related value includes at least one energy-related characteristic, the energy-related characteristic including magnitude, direction, phase angle, percentage, ratio, level, duration, associated frequency components, impedance, energy-related parameter shape, and/or decay rate. It is understood that many other derived energy-related value(s) are possible, as will be apparent to one of ordinary skill in the art.

In accordance with embodiments of this disclosure, the time-domain energy-related signals may be captured at the motor's energizing/start-up and/or during its energized/normal operation.

At block 704, the time-domain energy-related signals are processed to determine an operating state of the at least one motor. In accordance with embodiments of this disclosure, the operating state of the at least one motor may be at least one of energizing/starting, in a normal operating state/running, or not operating. It is understood that other operating states of the at least one motor are of course possible.

At block 706, it is determined if the operating state of the at least one motor indicates the at least one motor is at least one of energizing/starting and in a normal operating state/running. If it is determined the operating state of the at least one motor indicates the at least one motor is at least one of energizing/starting and in a normal operating state/running, the method proceed to block 708. Alternatively, if it is determined the operating state of the at least one motor does not indicate the at least one motor is at least one of energizing/starting and in a normal operating state/running (i.e., indicates the at least one motor is in another operating state), the method may end or return to block 702 in some embodiments.

At block 708, in response to determining the operating state of the at least one motor indicates the at least one motor is at least one of energizing/starting and in a normal operating state/running at block 706, the time-domain energy-related signals are converted to frequency representations of the time-domain energy-related signals. In accordance with some embodiments of this disclosure, the time-domain energy-related signals are transformed into the frequency-domain using a function and/or process such as a short-term Fourier transformer, discrete Fourier transformer, Goertzel algorithm, or any other viable technique.

At block 710, at least one of power data and impedance data is calculated/determined at one or more frequencies in the frequency-domain from the frequency representations of the time-domain energy-related signals. In accordance with some embodiments of this disclosure, the power data and/or impedance data is calculated/determined by converting the respective voltage and current spectral data (from block 708) into a combined spectrum of power and/or impedance. This may be performed, for example, by multiplying (i.e., for power) or dividing (i.e., for impedance) voltage and current at each respective frequency determined from the process at block 708. Apparent power, real power, reactive power, and impedance (including at least one of reactance and resistance) may be determined from the given set of data by incorporating the phase angle differences between the voltage and current at each respective frequency determined at block 708.

At block 712, at least the determined power data and/or the determined impedance data (i.e., the output of block 710) is analyzed at the one or more frequencies to identify an issue (or issues) associated with the at least one motor at least one of being in an energizing/starting condition and/or being in a normal operating state/steady-state/running condition. For example, the determined power data and/or the determined impedance data may be analyzed for changes at each, any or all frequencies to identify/determine changes over time. In accordance with embodiments of this disclosure, the determined power data and the determined impedance data are indicative of the issue(s) associated with the at least one motor at least one of being in an energizing/starting condition and/or being in a normal operating state/steady-state/running condition.

At block 714, which is optional in some embodiments, one or more actions are taken in response to at least one issue associated with the at least one motor at least one of being in an energizing/starting condition and/or being in a normal operating state/steady-state/running condition being identified at block 712. In accordance with some embodiments of this disclosure, the one or more actions include: identifying at least one means for addressing the at least one issue associated with the at least one motor at least one of being in an energizing/starting condition and/or being in a normal operating state/steady-state/running condition, and applying at least one of the at least one identified means for addressing the at least one issue associated with the at least one motor at least one of being in an energizing/starting condition and/or being in a normal operating state/steady-state/running condition. As noted in the Summary Section of this disclosure, there are many possible actions that may be taken in response to identifying at least one issue associated with the at least one of being in an energizing/starting condition and/or being in a normal operating state/steady-state/running condition.

In accordance with some embodiments of this disclosure, the one of more actions taken at block 714 may be performed by one or more systems and/or devices. For example, in some embodiments the actions may be performed by the at least one IED responsible for capturing the time-domain energy-related signals. In other embodiments, the actions may additionally or alternatively be performed by a control system (e.g., in embodiments in which the at least one IED does not correspond to the control system). The control system may be electrically coupled to the at least one IED, the at least motor, an Edge, gateway, cloud-based system, and/or other components in or associated with a system (e.g., electrical/power system) including the at least one IED and the at least one motor. It is understood that the one or more actions may additionally or alternatively be performed by a user associated with the system, for example, in response to recommendations provided by the at least one IED, the control system, the at least motor, the Edge, the gateway, the cloud-based system, and/or the other components in or associated with the system. The recommendations (e.g., for responding to issue(s) with the at least one motor) may be provided using the analytics described in this disclosure, for example.

Subsequent to block 714, the method may end in some embodiments. In other embodiments, the method may return to block 702 and repeat again (e.g., for capturing additional time-domain energy-related signals). In some embodiments in which the method ends after block 702, the method may be initiated again in response to user input and/or a control signal, for example.

It is understood that flow diagram 700 may include one or more additional blocks or steps in some embodiments, as will become apparent from discussions below about flow diagram 800.

Referring further to FIG. 7, in accordance with some embodiments of this disclosure, the method illustrated by FIG. 7 is inherently limited by the Nyquist frequency, which is based on the sampling rate of the IED(s) measuring/capturing/determining the time-domain energy-related signals (e.g., voltage and current signals) captured at block 702. It is strongly recommended (albeit not necessarily required) to eliminate signal aliasing by incorporating anti-aliasing filters (e.g., low-pass filters). Longer waveform captures facilitate more resolution in the frequency-domain; however, this may not be achievable during the start-up of a motor. In either case, comparative historical analysis should be as consistent as possible from data set to (subsequent) data set.

As illustrated by FIG. 7, and as will become further apparent from discussions below, analyzing energy-related data in the frequency-domain (e.g., harmonics/interharmonics/sub-harmonics) provides further insights into potential motor issues that may be arising. For example, motor rotors often experience cracked or broken rotor bars, dynamic eccentricity and/or bearing damage that change the motor's rotating flux and/or field components. Changes in the motor's rotating flux components are reflected in the motor current signals, which are measurable using IEDs. Evaluating the motor's power data and impedance data (via the process described above) accounts for variations in the motor's source voltage, leading to a more consistent analysis from start to start.

In this invention, the time-domain energy-related signals may be “transformed” into the frequency-domain independently from each other, preferably at the same sample rate (e.g., at block 708). The coincident frequency spectrum of the two transformed signals are then combined at one or more discrete frequencies (via power and/or impedance calculations) to normalize successive data captures. The respective product (e.g., power) and/or quotient (e.g., impedance) of the two terms may include a magnitude term and an angle term. As previously stated, it is important to limit the voltage and current signals (e.g., by low-pass or anti-aliasing filters) to the inherent constraints of the signal sampling rate to ensure signal aliasing errors are not introduced.

The magnitude term of the combined signal (e.g., power and/or impedance, at block 710) provides an indication of the severity at a particular frequency, and the angle term provides an indication of the direction the respective power is flowing (into or out of the load). For example, broken rotor bars in an induction motor are indicated by an increase in the upper and lower sidebands associated with a motor's slip frequency (i.e., (1±2 s)fₒ, where s is the motor's slip frequency and fₒ is the system frequency). As the number of broken rotor bars in the motor increase, the magnitude term of the sideband frequencies also increases. The angle term of the discrete frequencies (including the sideband frequencies) indicates whether the power flow at a given frequency is flowing into or out of the motor (with respect to the location/placement of the IED capturing the voltage and current signals). This direction of flow is dependent on whether the motor is a harmonic/interharmonic source (e.g., generator/supply) or sink (e.g., load) at a particular frequency. It is possible for a single load to be a source at one or more frequencies while being a sink at one or more other/different frequencies.

Referring now to FIG. 8, a flow diagram 800 is shown to illustrate another example method for analyzing operation of a motor in accordance with embodiments of this disclosure. In accordance with some embodiments of this disclosure, the method illustrated by flow diagram 800 corresponds to an example implementation of the method illustrated by flow diagram 600 including various concepts from the method illustrated by flow diagram 700. For this reason, several similar reference designations from flow diagram 600 are used in flow diagram 800.

As illustrated in FIG. 8, the method shown by the flow diagram or algorithm 800 begins at block 801, where it is determined if the at least one motor is starting/energizing. In accordance with embodiments of this disclosure, this is determined based on an analysis of time-domain energy-related signals captured by at least one IED electrically coupled to the at least one motor. If it is determined that the at least one motor is starting/energizing (i.e., in a startup period), the method may proceed to block 803. In accordance with some embodiments of this disclosure, this determination may be done by analyzing the current/power data to identify significate changes in their values (i.e., changing state from zero amps/zero watts to non-zero value), generally indicating the motor is in an energizing/starting condition. It is understood that other characteristics that may be analyzed to determine the at least one motor is in an energizing/starting condition. For example, the voltage profile (due to the system impedance and inrush current) associated with the at least one motor energizing/starting is generally indicative of a motor starting condition. Returning now to block 801, if it is determined that the at least one motor is not starting/energizing, the method may proceed to block 802.

If the motor is starting/energizing (801), Fourier analysis is performed on the time-domain energy-related signals (803) to convert the time-domain energy-related signals to frequency representations of the time-domain energy-related signals, and the algorithm associated with the method uses time-domain and/or frequency-domain power values and/or impedance values corresponding to starting current and/or voltage (804). Otherwise, if the motor is in a normal operating state/running (802), Fourier analysis is performed on the time-domain energy-related signals (805) to convert the time-domain energy-related signals to frequency representations of the time-domain energy-related signals, and the algorithm associated with the method uses time-domain and/or frequency-domain impedance/power values corresponding to run current and/or voltage (806). In accordance with some embodiments of this disclosure, the operational condition of the motor (i.e., starting or running) determines “which and how” algorithms are used to convert the time-domain energy-related signals in the frequency-domain. For example, a standard FFT approach may be used for data from a motor operating in a steady-state condition. Alternatively, a short-term Fourier transformer (SIFT) may be used to better analyze a motor that is starting.

Similar to the method illustrated by flow diagram 600, when a measured value is compared against a baseline by the baseline module 124 in the method illustrated by flow diagram 800, the baseline includes values or calculations determined during the starting or running periods of motor operation or using theoretical or rated values under LRA or FLA conditions.

After determining whether to use starting current/locked-rotor amps (LRA) or run current/full-load amps (FLA) functions or values, the algorithm 800 uses the current module 114 and the voltage module 116 to measure the voltage across the terminals 110a,b of the motor 102 and the current drawn by the motor during the starting or run current period (including the sampled waveform data), whichever is applicable (807). In the case of starting current, the current module 114 of the intelligent electronic device (IED) 100 receives a measured inrush current flowing into the induction motor 102 during a startup period of the induction motor 102 (807). Simultaneously with receiving the measured current, the voltage module of the at least one IED 100 receives a voltage measured across its power terminals 110a,b during the same startup period (807). The measured voltage and current can be stored in the database 126.

The algorithm 800 determines a voltage variation between the measured voltage and a rated/nominal voltage, which can be retrieved from the motor nameplate data 134 (808). The difference between the measured and rated/nominal voltage(s) produces a voltage variation, and the power flows into the motor and/or the impedance of the motor can be normalized to the voltage and compared against a baseline to account for the voltage variation at the motor's terminals 110a,b. The voltage variation may additionally or alternatively be determined using a look-up table, for example. For example, the voltage variation between the measured voltage and the rated/nominal voltage can be ascertained from the look-up table (e.g., stored on at least one memory device associated with a system including the at least one IED) based on the typical voltage values measured by the at least one IED. It is understood that these are but a few of many possible ways of detecting the voltage variation, as will be apparent to one of ordinary skill in the art.

Returning now to algorithm 800, the characteristic function module 122 calculates motor impedance using measured voltage and current values in the time-domain and/or frequency-domain (810). The determined impedance data can be stored in the database 126 along with a corresponding timestamp indicating a time that the current and voltage were measured.

At block 814, the algorithm 800 can do a statistical analysis of motor impedance with regards to motor impedance for time-domain and/or frequency-domain corresponding to starting current and/or run current. The algorithm 800 can compare, using a statistical analysis carried out by the statistical module 128, the determined motor impedance from the time-domain and/or frequency-domain with theoretical motor impedance corresponding the starting current/run current to determine whether a criterion is satisfied (812). When the determined motor impedance at the voltage variation varies from a statistical comparison of theoretical motor impedance at the same voltage variation, the algorithm 800 can determine that the criterion is satisfied. The criterion can include whether a statistically significant outcome exists as a result of the statistical comparison carried out by the statistical module 128 or whether the statistical comparison produces a probability or likelihood that the measured impedance varies significantly from the theoretical motor impedance (which may correspond to a baseline impedance). The criterion being satisfied may be indicative an anomaly existing relative to the induction motor 102. The criterion can be satisfied, for example, when the measured impedance deviates from the theoretical impedance at the voltage variation by more than a fixed threshold, a relative threshold (such as expressed as a percentage), or based on a statistical threshold such as a standard deviation.

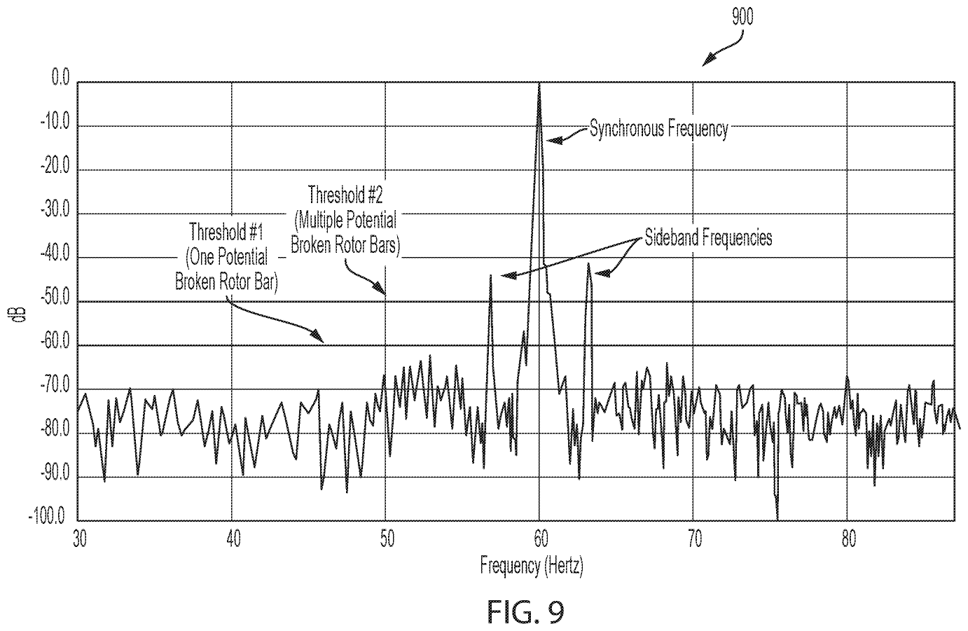

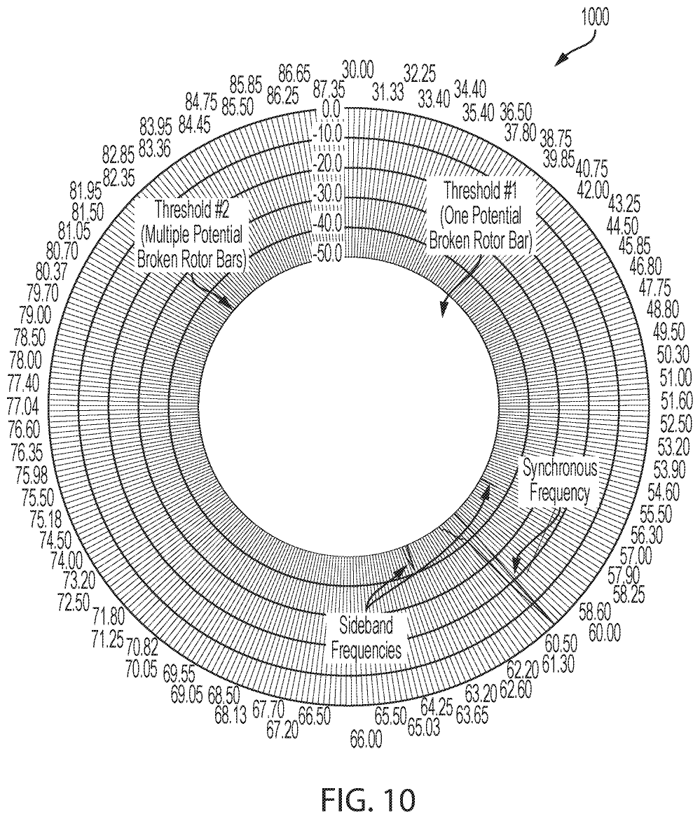

If the criterion is satisfied, the alarm module 130 can provide at least one alarm (816) and/or at least one report indicating a trend (or trends), an alarm (or alarms), or relevant and/or significant change(s) to electrical parameter(s) (818), for example. The alarm(s), for example, may be based on absolute, relative, or statistical thresholds using time-domain data and/or frequency-domain data. In accordance with some embodiments of this disclosure, the alarm(s) may be prioritized and be presented in order of priority, for example, in the report(s). In accordance with some embodiments of this disclosure, the prioritization may be based on any number of factors. For example, referring also to FIGS. 9 and 10, the prioritization can be based on magnitude of at least one of the sidebands, ratio of the sideband(s) to the fundamental frequency, and/or at least one specific frequency component(s) being considered/evaluated/measured, as a few examples.

With respect to the report(s), the report(s) can indicate how the motor's impedance is trending over time on a plot, for example, to provide a visual indication of the motor's successive impedance characteristics during starting and/or run current periods. Deviations from the motor's impedance from nominal or baseline will be normalized to the voltage so that any voltage variation will be accounted for in the trend report. The report can indicate an alarm and the nature of the alarm. For example, if the impedance is higher than expected, the report can indicate potential damage to the motor's rotor or rotor bars or a potential poor connection relative to the motor's terminals 110a,b or a potential intermittent or poor connection with one or more of the stator windings of the motor. If the impedance is lower than expected, the report can indicate a potential short-circuit in a winding or windings of a coil around a pole of the motor 102 or between adjacent coils of the motor or a potential insulation breakdown that might be caused by vibration or thermal/electrical stress in the windings. The report can indicate a significant change to an electrical parameter, such as the impedance of, or power flow to, the motor 102. If the impedance or power flow decreases or increases suddenly, beyond nominal or baseline expectations, the report can indicate that immediate attention may be warranted. The output of blocks 616 and 618 can be stored in the database 126. The report can be communicated via the interface 132 to another system, such as a computer that includes a display device for displaying the report.

At block 820, the algorithm 800 checks whether the motor is running at a full load, and if so, returns to block 806. At block 806, the motor has completed its startup period and is operating at its nominal running current, which means that the motor is rotating a load 108 at or near the expected design speed of the motor 102. The length of time that the motor 102 takes to achieve nominal operation varies by the motor and can be programmed into the algorithm 800. For example, the power flow into the motor 102 can be monitored and when it reaches a relatively stable value (see FIG. 3, for example, starting at about 3 seconds after motor initial startup), the algorithm 800 can determine that the motor 102 is operating under nominal or steady-state conditions. Alternately, a fixed time, such as 3 or 5 seconds or some other wait period after the motor is turned on can be determined to be the normal running period. The characteristic function module 122 calculates a power flow (real power, reactive power, or apparent power) from the measured voltage and the inrush or nominal (steady-state) current drawn by the motor under starting or running conditions (822) in the time-domain and/or frequency-domain. The algorithm 800 determines the voltage variation between the measured voltage during starting or nominal conditions and the rated voltage from the motor nameplate data 134 (824). The statistical module 128 evaluates or compares the measured (determined from the measured voltage and current) power flow (e.g., real, reactive, or apparent) in the time-domain and/or frequency-domain at the voltage variation (see FIGS. 3-4 for example) against historical power flow data for starting or running periods stored in the database 126 at or near the same voltage variation (826). Thus, if the motor is just starting and the current to the motor approximately corresponds to a locked-rotor current, the characteristic function module 122 calculates the power flow at the voltage variation (e.g., 465V or +5V from the nominal or rated voltage of 460V) at startup of the motor 102, such as shown in FIG. 3. This determined value is compared by the statistical module 128 against historical power flow data at the same voltage variation using statistical analysis to determine whether the determined value deviates in a statistically significant way from the baseline or expected or theoretical power flow.

Alternately or additionally, the algorithm 800 can evaluate and/or compare the power flow value determined from the measured starting or run (steady-state) current and the associated motor voltage from the time-domain and/or frequency-domain with a theoretical or expected or baseline power flow value at the same voltage variation using the rated LRA or FLA current and the rated voltage from the motor nameplate data 134 and the voltage variation (see FIG. 3) (828) in the time-domain and/or frequency-domain. The algorithm 800 proceeds to block 816 and optionally to block 818 as described above.

The baseline can correspond to a theoretical function that includes a rated LRA or FLA current and the rated voltage. The database 126 can store these theoretical functions (e.g., corresponding to impedance and/or power flow) along with the corresponding voltage variation for the starting period and separately for the normal operational period of motor.

Referring now to FIGS. 9 and 10, multiple figures are shown to illustrate how the systems and methods disclosed herein (particularly, methods 700 and 800) may be applied and found useful. FIGS. 9 and 10 illustrate power data plots 900 and 1000 from an induction motor load in the frequency-domain. The motor's synchronous frequency (i.e., system frequency), two sideband frequencies (i.e., (1±2 s)fₒ), and two thresholds are provided in each graphs. The synchronous frequency will always be large because it is the “intentional” (i.e., nominal) frequency of the signals provided by the source (e.g., 60 Hz). The two sideband frequencies of the induction motor will always be present; however, their magnitude is generally dependent on the health of the motor. In this example, the sideband frequencies magnitudes increase as additional rotor bars are damaged (e.g., cracked or broken), typically due to repetitive starting stresses (and resulting temperature variations) associated with short duty-cycles, starting loads, and/or longer start times.

FIGS. 9 and 10 illustrate two thresholds that provide different respective severities of issues associated with broken rotor bars. The first threshold (Threshold #1) indicates the potential for at least one cracked or broken rotor bar on the induction motor; the second threshold (Threshold #2) indicates the potential for multiple cracked or broken rotor bars on the induction motor. These thresholds may be manually or automatically determined and configured using absolute power values (e.g., real, reactive, apparent), relative values (e.g., percentage), or some other value such as ratios (e.g., dB).

The systems and methods disclosed herein allow the user to better analyze motor issues by comparing data load conditions with other historically similar load conditions for better consistency. That is to say, the uniformity and outcome of evaluating a motor's condition is improved when the analyses are compared during similar operational conditions. Therefore, additional improvements (beyond basic analyses of power and impedance in the frequency-domain) may be made by examining historical trends of said data by first comparing the fundamental frequency component for similarities across data sets. If reasonable similarities are established between the fundamental frequencies of two or more voltage, current, power, and/or impedance data sets, comparisons of changes/trends in relevant non-fundamental frequencies (e.g., sideband frequencies) is more effective and compelling.

For example, the magnitude of an induction motor's sidebands with two cracked or broken rotor bars may be significantly different at 50% of load versus 100% of load. Ensuring a relative consistency of the power and/or impedance at the fundamental frequency (e.g., 50 Hertz, 60 Hertz) when comparing two data sets in the frequency-domain improves the results.

Another supplemental feature considered by this invention is incorporating a motor's duty-cycle and start time data into the time-domain and frequency-domain analyses. Duty-cycle generally refers to the sequence and durations in time of all aspects of a characteristic operation, including start, run with no load, run with full load, electric braking, and rest. The duty-cycle of a motor affects its temperature, so it is useful to determine the correct motor application, whether additional/increased cooling is needed, or whether the motor is/is not suitable for its application.

Evaluating magnitude and directional changes in the frequency-domain over time can provide interesting information as it relates to a motor's duty-cycle. Motors that are started frequently or take longer to start experience more stress, potentially resulting in shorter life expectancies due to failure modes identifiable in advance. For example, broken rotor bars often occur due to electrically induced mechanical strain. Analyzing the duty-cycle characteristics against changes in frequency-domain components is a useful technique to predict and resolve motor maintenance issues.

Because polyphase induction motors are often critical components in many industrial processes, their reliability is essential to a business's bottom line. There are many potential hazards both internal and external to the motor that can reduce its operating life or cause the motor to unexpectedly fail. Continuously evaluating a motor's electrical characteristics is a valuable tool to identify potential motor issues to reduce unscheduled maintenance (or increase planned maintenance).

While many of the systems and methods disclosed herein are discussed with reference to induction motors, it is understood that these methods can be applied to other electrical apparatuses besides induction motors such as transformers and lighting.

It is understood that FIGS. 6-8, described by way of example above, represent one or more algorithms that correspond to at least some instructions executed by the one or more controllers 120 to perform the above described functions or steps. Any of the methods or algorithms or functions described herein can include machine or computer-readable instructions for execution by: (a) a processor, (b) a controller 120, and/or (c) any other suitable processing device. Any algorithm, software, or method disclosed herein can be embodied as a computer program product having one or more non-transitory tangible medium or media, such as, for example, a flash memory, a CD-ROM, a floppy disk, a hard drive, a digital versatile disk (DVD), or other memory devices, but persons of ordinary skill in the art will readily appreciate that the entire algorithm and/or parts thereof could alternatively be executed by a device other than a controller and/or embodied in firmware or dedicated hardware in a well-known manner (e.g., it may be implemented by an application specific integrated circuit (ASIC), a programmable logic device (PLD), a field programmable logic device (FPLD), discrete logic, etc.).

While particular aspects and implementations of the present disclosure have been illustrated and described, it is to be understood that the present disclosure is not limited to the precise construction and compositions disclosed herein and that various modifications, changes, and variations are not only contemplated but also apparent from the foregoing descriptions without departing from the scope of the present disclosure as defined in the appended claims.

What is claimed is:

1. A method for analyzing operation of a motor, comprising:
capturing time-domain energy-related signals associated with at least one motor using at least one intelligent electronic device (IED) electrically coupled to the at least one motor;
processing the time-domain energy-related signals to determine an operating state of the at least one motor;
in response to determining the operating state of the at least one motor indicates the at least one motor is at least one of being in an energizing/starting condition and being in a normal operating state/steady-state/running condition, converting the time-domain energy-related signals to frequency representations of the time-domain energy-related signals;
determining at least one of power data and impedance data at one or more frequencies in the frequency-domain from the frequency representations of the time-domain energy-related signals; and
analyzing at least one of the determined power data and/or the determined impedance data at the one or more frequencies to identify an issue associated with the at least one motor at least one of being in an energizing/starting condition and/or being in a normal operating state/steady-state/running condition, wherein at least one of the determined power data and the determined impedance data are indicative of the issue associated with the at least one motor at least one of being in an energizing/starting condition and/or being in a normal operating state/steady-state/running condition.

2. The method of claim 1, wherein analyzing at least one of the determined power data and/or the determined impedance data at the one or more frequencies to identify an issue associated with the at least one motor at least one of being in an energizing/starting condition and/or being in a normal operating state/steady-state/running condition, includes: analyzing other relevant information to identify the issue associated with the at least one motor at least one of being in an energizing/starting condition and/or being in a normal operating state/steady-state/running condition.

3. The method of claim 2, wherein the other relevant information includes duty-cycle information.

4. The method of claim 1, further comprising: providing recommendations for responding to the identified issue.

5. The method of claim 1, wherein characteristics of the at least one of the determined power data and/or the determined impedance data at the one or more frequencies are analyzed and/or trended over time to identify the issue associated with the at least one motor at least one of being in an energizing/starting condition and/or being in a normal operating state/steady-state/running condition.

6. The method of claim 1, wherein the one or more frequencies include at least one of harmonic frequency component(s), interharmonic frequency component(s), and sub-harmonic frequency component(s).

7. The method of claim 1, wherein the one or more frequencies include a fundamental frequency/nominal system frequency, and wherein analyzing at least one of the determined power data and/or the determined impedance data at the one or more frequencies to identify an issue associated with the at least one motor at least one of being in an energizing/starting condition and/or being in a normal operating state/steady-state/running condition, includes:
comparing the at least one of the determined power data and/or the determined impedance data at the fundamental frequency/nominal system frequency to the previously at least one of determined power data and/or previously determined impedance data at the fundamental frequency/nominal system frequency;
identifying a relative similarity of the at least one of the determined power data and/or the determined impedance data at the fundamental frequency/nominal system frequency and the previously determined power data and/or the previously determined impedance data at the fundamental frequency/nominal system frequency; and
analyzing the relative similarity of the at least one determined power data and/or the determined impedance data and the previously determined power data and/or the previously determined impedance data on at least one non-fundamental frequency to identify the issue associated with the at least one motor at least one of being in an energizing/starting condition and/or being in a normal operating state/steady-state/running condition.

8. The method of claim 1, wherein analyzing at least one of the determined power data and/or the determined impedance data at the one or more frequencies to identify an issue associated with the at least one motor at least one of being in an energizing/starting condition and/or being in a normal operating state/steady-state/running condition, includes:
analyzing at least one of the determined power data and/or the determined impedance data in at least one of the time-domain and frequency-domain against duty-cycle characteristics of the at least one motor to identify the issue associated with the at least one motor at least one of being in an energizing/starting condition and/or being in a normal operating state/steady-state/running condition.

9. The method of claim 8, wherein the duty-cycle characteristics of the at least one motor include at least one of: starting characteristics of the at least one motor, running characteristics of the at least one motor, and inoperative characteristics of the at least one motor.

10. The method of claim 9, wherein the at least one of: the starting characteristics of the at least one motor, the running characteristics of the at least one motor, and the inoperative characteristics of the at least one motor, include: at least one of a starting duration of the at least one motor, run duration of the at least one motor, period(s) between starts of the at least one motor, period(s) between the at least one motor being de-energized/turned-off and the at least one motor being energized/turned-on, and load of the at least one motor when energized/started.

11. The method of claim 1, further comprising:
taking one or more actions in response to identifying at least one issue associated with the at least one motor at least one of being in an energizing/starting condition and/or being in a normal operating state/steady-state/running condition.

12. The method of claim 11, wherein taking one or more actions in response to identifying at least one issue associated with the at least one motor at least one of being in an energizing/starting condition and/or being in a normal operating state/steady-state/running condition, includes:
identifying at least one means for addressing the at least one issue associated with the at least one motor at least one of being in an energizing/starting condition and/or being in a normal operating state/steady-state/running condition; and
applying at least one of the at least one identified means for addressing the at least one issue associated with the at least one motor at least one of being in an energizing/starting condition and/or being in a normal operating state/steady-state/running condition.

13. The method of claim 12, wherein the at least one of the at least one identified means for addressing the at least one issue associated with the at least one motor at least one of being in an energizing/starting condition and/or being in a normal operating state/steady-state/running condition is applied based on at least one of the priority and severity of the at least one issue.

14. The method of claim 12, wherein the at least one of the at least one identified means for addressing the at least one issue associated with the at least one motor at least one of being in an energizing/starting condition and/or being in a normal operating state/steady-state/running condition is automatically applied.

15. The method of claim 12, wherein the at least one of the at least one identified means for addressing the at least one issue associated with the at least one motor at least one of being in an energizing/starting condition and/or being in a normal operating state/steady-state/running condition is applied, at least in part, in response to user input.

16. The method of claim 12, wherein the at least one of the at least one identified means for addressing the at least one issue associated with the at least one motor at least one of being in an energizing/starting condition and/or being in a normal operating state/steady-state/running condition is selected based, at least in part, on user-specified criteria.

17. The method of claim 12, wherein the at least one of the at least one identified means for addressing the at least one issue associated with the at least one motor at least one of being in an energizing/starting condition and/or being in a normal operating state/steady-state/running condition is selected based on an analysis of a number of learned factors or criteria.

18. The method of claim 12, wherein the one or more actions include:
generating and/or initiating at least one alarm indicating the at least one identified issue or potential issue(s).

19. The method of claim 18, wherein the at least one alarm indicates at least one of: change in power, change in energy, change in phase imbalance, change in voltage, change in power factor, change in one or more harmonic/interharmonic/sub-harmonic power flow directions, change in harmonic distortion, change in current, change in any other measured and/or derived parameter, and/or changes in digital and/or analog inputs and/or outputs.

20. The method of claim 18, further comprising:
communicating the at least one alarm via at least one of: a report, a text, an email, audibly, and an interface of a screen/display.

21. The method of claim 1, wherein the time-domain energy-related signals captured using the at least one IED include at least one of: a voltage signal, a current signal, and/or a derived energy-related value.

22. The method of claim 21, wherein the derived energy-related value includes at least one of: a calculated, computed, estimated, derived, developed, interpolated, extrapolated, evaluated, and otherwise determined additional energy-related value from the at least one of the voltage signal and/or the current signal.

23. The method of claim 21, wherein the derived energy-related value includes at least one of: active power(s), apparent power(s), reactive power(s), energy(ies), harmonic distortion(s), power factor(s), magnitude/direction of harmonic power(s), harmonic voltage(s), harmonic current(s), interharmonic current(s), interharmonic voltage(s), magnitude/direction of interharmonic power(s), magnitude/direction of sub-harmonic power(s), individual phase current(s), phase angle(s), impedance(s), sequence component(s), total voltage harmonic distortion(s), total current harmonic distortion(s), three-phase current(s), phase voltage(s), line voltage(s) and/or other similar/related parameters.

24. The method of claim 21, wherein the derived energy-related value includes at least one energy-related characteristic, the energy-related characteristic including magnitude, direction, phase angle, percentage, ratio, level, duration, associated frequency components, impedance, energy-related parameter shape, and/or decay rate.

25. The method of claim 1, wherein the at least one IED includes at least one metering device.

26. A system for analyzing operation of a motor, comprising:
a processor;
a memory device coupled to the processor, the processor and the memory device configured to:
capture time-domain energy-related signals associated with at least one motor;
process the time-domain energy-related signals to determine an operating state of the at least one motor;
in response to determining the operating state of the at least one motor indicates the at least one motor is at least one of being in an energizing/starting condition and being in a normal operating state/steady-state/running condition, converting the time-domain energy-related signals to frequency representations of the time-domain energy-related signals; and
determining at least one of power data and impedance data at one or more frequencies in the frequency-domain from the frequency representations of the time-domain energy-related signals; and
analyze at least one of the determined power data and/or the determined impedance data at the one or more frequencies to identify an issue associated with the at least one motor at least one of being in an energizing/starting condition and/or being in a normal operating state/steady-state/running condition, wherein the determined power data and the determined impedance data are indicative of the issue associated with the at least one motor at least one of being in an energizing/starting condition and/or being in a normal operating state/steady-state/running condition.

27. The system of claim 26, wherein the time-domain energy-related signals are captured by at least one IED in the system, the at least one IED electrically coupled to the at least one motor.

28. The system of claim 26, wherein the at least one motor corresponds to a plurality of motors, and the time-domain energy-related signals for each motor of the plurality of motors are captured by at least one IED in the system, the at least one IED electrically coupled to the plurality of motors.

29. The system of claim 26, wherein characteristics of the at least one of determined power data and/or the determined impedance data at the one or more frequencies are analyzed and/or trended over time to identify the issue associated with the at least one motor at least one of being in an energizing/starting condition and/or of being in a normal operating state/steady-state running condition.

30. A method for analyzing operation of a motor, comprising:
capturing time-domain energy-related signals associated with at least one motor using at least one intelligent electronic device (IED) electrically coupled to the at least one motor;
processing the time-domain energy-related signals to determine an operating state of the at least one motor;
in response to determining the operating state of the at least one motor indicates the at least one motor being in an energizing/starting condition and being in a normal operating state/steady-state/running condition, converting the time-domain energy-related signals to frequency representations of the time-domain energy-related signals; and
analyzing the frequency representations of the time-domain energy-related signals to identify an issue associated with the at least one motor at least one of being in an energizing/starting condition and/or being in a normal operating state/steady-state/running condition, wherein characteristics of the frequency representations are indicative of the issue associated with the at least one motor at least one of being in an energizing/starting condition and being in a normal operating state/steady-state/running condition.
